(19) United States
(12) Patent Application Publication
(10) Pub. No.: US 2016/0122580 A1
(43) Pub. Date: May 5, 2016

(54) DEFECT REDUCTION METHODS AND COMPOSITION FOR VIA FORMATION IN DIRECTED SELF-ASSEMBLY PATTERNING

(71) Applicant: AZ ELECTRONIC MATERIALS (LUXEMBOURG) S.A.R.L., Somerville, NJ (US)

(72) Inventors: SungEun HONG, Basking Ridge, NJ (US); Naoki MATSUMOTO, Shizuoka (JP); Yasushi AKIYAMA, Shizuoka (JP); Kazunori KUROSAWA, Shizuoka (JP); Shinji MIYAZAKI, Shizuoka (JP); Guanyang LIN, Whitehouse Station, NJ (US)

(21) Appl. No.: 14/527,962

(22) Filed: Oct. 30, 2014

(51) Int. Cl. C09D 153/00; H01J 37/32

(52) U.S. Cl. CPC C09D 153/00; H01J 37/32009

(57) ABSTRACT

The present invention relates to a two novel processes, “Dual Coating Process and Single Coating Process,” for forming an array of via's by employing a graphoepitaxy approach, where an array of pillars the surface of the pillars has been modified by the formation of a hydrophobic poly(vinyl aryl) brush at the surface of the pillars. The present invention also relates to a composition comprising a poly(vinyl aryl) hydrophopic polymer brush precursor terminated at one chain end with a reactive functional group, a diblock copolymer comprising an etch resistant hydrophobic block and a highly etchable hydrophilic block, a thermal acid generator and a solvent.

### FIELD OF THE INVENTION

The invention relates to processes and compositions for reducing defects in via's formed through patterning formed by directed self-assembling of block copolymers (BCP) to form a via array from an array of posts. The processes are useful for fabrication of electronic devices.

### BACKGROUND

Directed self-assembly of block copolymers is a method useful for generating smaller and smaller patterned features for the manufacture of microelectronic devices in which the critical dimensions (CD) of features on the order of nanoscale can be achieved. Directed self-assembly methods are desirable for extending the resolution capabilities of microlithographic technology. In a conventional lithography approach, ultraviolet (UV) radiation may be used to expose through a mask onto a photoresist layer coated on a substrate or layered substrate. Positive or negative photoresists are useful and these can also contain a refractory element such as silicon to enable dry development with conventional integrated circuit (IC) plasma processing. In a positive photoresist, UV radiation transmitted through a mask causes a photochemical reaction in the photoresist such that the exposed regions are removed with a developer solution or by conventional IC plasma processing. Conversely, in negative photoresists, UV radiation transmitted through a mask causes the regions exposed to radiation to become less removable with a developer solution or by conventional IC plasma processing. An integrated circuit feature, such as a gate, via or interconnect, is then etched into the substrate or layered substrate, and the remaining photoresist is removed. When using conventional lithographic exposure processes, the dimensions of the integrated circuit feature are limited. Further reduction in pattern dimensions are difficult to achieve with radiation exposure due to limitations related to aberrations, focus, proximity effects, minimum achievable exposure wavelengths and maximum achievable numerical apertures. The need for large-scale integration has led to a continued shrinking of the circuit dimensions and features in the devices. Direct assembly techniques, such as graphoepitaxy and chemoepitaxy using block copolymer imaging, are highly desirable techniques used to enhance resolution while reducing CD variation. These techniques can be employed to either enhance conventional UV lithographic techniques or to enable even higher resolution and CD control in approaches employing EUV, e-beam, deep UV or immersion lithography. The directed self-assembly block copolymer comprises a block of etch resistant copolymeric unit and a block of highly etchable copolymeric unit, which when coated, aligned and etched on a substrate give regions of very high density patterns.

In the graphoepitaxy directed self-assembly method, the block copolymers self-organize around a substrate that is pre-patterned with conventional lithography (Ultraviolet, Deep UV, e-beam, Extreme UV (EUV) exposure source) to form repeating topographical features such as a line/space (L/S) or contact hole (CH) pattern. In an example of a L/S directed self-assembly array, the block copolymer can form self-aligned lamellar regions which can form parallel line-space patterns of different pitches in the trenches between pre-patterned lines, thus enhancing pattern resolution by subdividing the space in the trench between the topographical lines into finer patterns. For example, a diblock copolymer which is capable of microphase separation and comprises a block rich in carbon (such as styrene or containing some other element like Si, Ge, Ti) which is resistant to plasma etch, and a block which is highly plasma etchable or removable, can provide a high resolution pattern definition. Examples of highly etchable blocks can comprise monomers which are rich in oxygen and which do not contain refractory elements, and are capable of forming blocks which are highly etchable, such as methyl methacrylate. The plasma etch gases used in the etching process of defining the self-assembly pattern typically are those used in processes employed to make integrated circuits (IC). In this manner very fine patterns can be created in typical IC substrates than were definable by conventional lithographic techniques, thus achieving pattern multiplication. Similarly, features such as contact holes can be made denser by using graphoepitaxy in which a suitable block copolymer arranges itself by directed self-assembly around an array of contact holes or posts defined by conventional lithography, thus forming a denser array of regions of etchable and etch resistant domains which when etched give rise to a denser array of contact holes. Consequently, graphoepitaxy has the potential to offer both pattern rectification and pattern multiplication.

In chemical epitaxy or pinning chemical epitaxy the self-assembly of the block copolymer is formed around a surface that has regions of differing chemical affinity but no or very slight topography to guide the self-assembly process. For example, the surface of a substrate could be patterned with conventional lithography (UV, Deep UV, e-beam EUV) to create surfaces of different chemical affinity in a line and space (L/S) pattern in which exposed areas whose surface chemistry had been modified by irradiation alternate with areas which are unexposed and show no chemical change. These areas present no topographical difference, but do present a surface chemical difference or pinning to direct self-assembly of block copolymer segments. Specifically, the directed self-assembly of a block copolymer whose block segments contain etch resistant (such as styrene repeat unit) and rapidly etching repeat units (such as methyl methacrylate repeat units) would allow precise placement of etch resistant block segments and highly etchable block segments over the pattern. This technique allows for the precise placement of these block copolymers and the subsequent pattern transfer of the pattern into a substrate after plasma or wet etch processing. Chemical epitaxy has the advantage that it can be fined tuned by changes in chemical differences to help improve line-edge roughness and CD control, thus allowing for pattern rectification. Other types of patterns such as repeating contact holes (CH) arrays could also be pattern rectified using chemoepitaxy.

Neutral layers are layers on a substrate or the surface of a treated substrate which has no affinity for either of the block segments of a block copolymer employed in directed self-assembly. In the graphoepitaxy method of directed self-assembly of block copolymer, neutral layers are useful as they allow the proper placement or orientation of block polymer segments for directed self-assembly which leads to proper placement of etch resistant block polymer segments and highly etchable block polymer segments relative to the substrate. For instance, in surfaces containing line and space features which have been defined by conventional radiation lithography, a neutral layer allows block segments to be oriented so that the block segments are oriented perpendicular to the surface of the substrates, an orientation which is ideal for both pattern rectification and pattern multiplication depending on the length of the block segments in the block copolymer as related to the length between the lines defined by conventional lithography.

The use of pillar/post guides for the formation of via arrays using a block copolymer directed self-assembly approach has been previously described (U.S. Pat. No. 8,486,511B2 and U.S. Pat. No. 8,486,512B2). However, there is no discussion in the background art of the problem of defects inherent to such a process and how to solve this problem.

### DESCRIPTION OF THE INVENTION

When using in a Graphoepitaxy approach an array of pillars on a substrate as guide for via formation into the substrate, a diblock copolymer comprised of a highly etchable hydrophilic block and an etch resistant hydrophobic block may be self-assembled around these pillars forming a highly etchable hydrophilic block domain at the center between a regular array of pillars, such as the center of a pillars arranged in a rectangular, triangular or square array. However, if the highly etchable block shows a preference for the surface of the pillars, highly etchable domain layer will also surrounding these pillars. During pattern transfer to form the Via array using either wet chemical development, or a dry plasma etch development, the presence of these highly etchable domains surrounding the pillars will cause large defect voids to form near the pillars. Thus, there is a need for a process to form Vias in which a layer surrounding the surface of the pillars will direct the hydrophobic etch resistant block domains to assemble at the surface of the pillars instead of the highly etchable bock polymer domains, thus allowing for the formation of Vias without defects. The present invention relates to two novel processes for forming a layer of a hydrophobic poly(vinyl aryl) based grafted polymer brush at the surfaces allowing for the pattern transfer of a self-assembled block copolymer to form a via array from the pillar array. In the first inventive process for forming a via array, the “Dual Coating Process,” a thin hydrophobic grafted layer is formed over the pillars. This is done by coating a solution composition comprising a poly(vinyl aryl) polymer terminated at one end with a reactive end group (polymeric brush precursor) on the pillars and applying a grafting bake followed by removal of ungrafted polymer, thus forming a hydrophobic polymeric brush coating on the surface of the pillars. This is followed by coating the pillars grafted with this polymer brush with a block copolymer, and affecting a flow bake. This flow bake is followed by an alignment bake in which the etch resistant hydrophobic domains of the block copolymer align towards the pillars coated with the grafted layer. Then in an imaging step, the block copolymer self-assembled around the array of pillars is developed by using either a wet or plasma etch process to form a pattern in which only the etch resistant hydrophobic self-assembled domains remain on the substrate. By using a plasma etch process, these domains are then pattern transferred into the substrate to form the array of vias.

In the second inventive process for making a via array, the “Single Coating Process,” the grafting of the layer and application of the block polymer is done in one step by employing a solution in a solvent comprised of a poly(vinyl aryl) polymer hydrophobic brush precursor and a block copolymer. This is coated over the pillar array to which is then applied a solvent removal, flow, and grafting bake, in which the poly(vinyl aryl) polymer grafts to the surface of the pillars. Once grafting is complete, this is followed by an annealing bake in which the block polymer domains self-assembles so as to align the hydrophobic etch resistant block domains with the pillars grafted with the poly(vinyl aryl) layer. Then in a imaging step the block copolymer self-assembled around the array of pillars is developed by using either a wet or plasma etch process to form a pattern in which only the etch resistant self-assembled domains remain on the substrate. These domains are then pattern transferred into the substrate to form the via array by using a plasma etch process.

The present invention also pertains to a novel coating composition for affecting the second inventive process, “Single Coating Process,” for making a via array from a pillar array. This novel composition is comprised of a poly(vinyl aryl) polymer precursor terminated at one end by a reactive functional group, a diblock copolymer comprised of a etch resistant hydrophobic block and highly etchable hydrophilic block, a solvent, and a thermal acid generator (TAG).

### BRIEF DESCRIPTION OF DRAWINGS

FIG. 1 shows a pillar in which hydrophilic polymethacrylate domains of the diblock copolymer poly(styrene-block-methyl methacrylate) have aligned themselves with the surface of a hydrophilic pillar.

FIG. 2a shows a pillar array with a self-assembled poly(styrene-block-methyl methacrylate) block copolymer in which the hydrophilic polymethylacrylate domains have formed a layer surrounding the hydrophilic pillar surfaces along with the central self-assembled poly(methyl methacrylate) domain in the center between the three pillars.

FIG. 2b shows a pillar array with a self-assembled polystyrene-block-methyl methacrylate) block Copolymer in which the hydrophobic etch domains have formed a layer surrounding the pillars grafted with a hydrophobic polystyrene hydroxyl terminated polymer.

FIG. 3 shows the formation of a via array using the “Dual Coating Process”.

FIG. 4 shows the formation of a via array using the “Single Coating Process”.

FIG. 5 shows a Post Guide Array (1) (Pillar size: 40˜100 nm and Pitch size: 80˜200 nm: Pillar height: 50˜200 nm).

FIG. 6 shows a Post Guide Array (2) (Pillar size: 40˜100 nm and Pitch size: 80˜200 nm: Pillar height: 50˜200 nm).

### SUMMARY OF INVENTION

The present invention relates to two novel processes, “Dual Coating Process and Single Coating Process,” for forming an array of via's by employing in a graphoepitaxy approach, an array of pillars in which the surface of the pillars has been modified by the formation of a polyvinyl aryl) based hydrophobic brush at the surface of the pillars. These processes avoid the formation of defects which otherwise would arise due to the assembly of highly etchable block copolymer domains around the pillar array instead of only in the center region between an assembly of pillars.

The “Dual Coating Process” comprises steps i) to vii) as follows: i) coating a planar thin film over a substrate comprising an original regular array of hydrophilic pillars from a first coating solution comprising a hydrophobic polymer brush precursor, and a solvent where the hydrophobic polymer brush precursor is comprised of vinyl aryl repeat units and where the polymer is terminated at one chain end by a reactive functional group chosen from the group consisting of hydroxyl (—OH), amino (—NH₂), phosphonic acid (—P═O(OH)₂) and phosphonic acid alkyl ester—P═O(OR)₂, where R is a C₁-C₄ alkyl group, and further where the thin film has a contact angle with water of about 75° to about 90°; ii) baking the thin film, thus grafting the reactive functional group terminated chain end of the hydrophobic polymer brush precursor to the hydrophilic surface on the coated pillars and thereby forming a hydrophobic coating on the pillars; iii) removing the non-grafted hydrophobic polymer brush precursor with a solvent; iv) coating the hydrophobic coated pillars with a second coating solution of a block copolymer in a solvent such than the coating film is conformal, and covers the pillars using a coating solution comprising the block copolymer and a solvent where the block copolymer is comprised of a hydrophobic etch resistant block and a hydrophilic highly etchable block; v) applying a flow bake to the block copolymer film so as to conformably fill the topography of the pillar array; vi) applying an annealing bake to affect self-assembly wherein the hydrophophic blocks of the block copolymer attach to the hydrophobic coated pillars; and, vii) developing the self-assembled structure to form the via array.

The “Single Coating Process” is a process for making multiple via's from an original regular array of hydrophilic pillar comprised of steps i) to iv) as follows: i) coating the original regular array hydrophilic pillars with a third coating solution such than the coating film is thick enough to cover the pillars wherein the coating solution is comprises a mixture of a) hydrophobic polymer brush precursor comprised of vinyl aryl repeat units where the polymer precursor is terminated at one chain end as above and further where the hydrophobic polymer brush precursor, if coated in a thin film by itself, has a contact angle with water of about 75° to about 90°; b) block copolymer and c) a solvent; and further wherein the block copolymer is comprised of an etch resistant hydrophobic block and a highly etchable hydrophilic block; ii) applying a flow and grafting bake to the coating film so as to conformably fill the topography of the pillar array and to graft the hydrophobic polymer brush precursor comprised of vinyl aryl repeat units terminated at one end by a reactive end group to the surface of the pillars; iii) applying an annealing bake to affect self-assembly, where the hydrophophic blocks of the block copolymer attach to the pillars; and iv) developing the self-assembled structure to form the via array.

The present invention also relates to a novel composition for making multiple vias employed in the “Single Coat Process,” comprised of a poly(vinyl aryl) hydrophobic polymer brush precursor where the hydrophobic polymer brush precursor, if coated in a thin film by itself, has a contact angle with water of about 75° to about 90° and is terminated at one chain end with a reactive functional group; a diblock copolymer comprised of an etch resistant hydrophobic block and a highly etchable hydrophilic block, solvent and a thermal acid generator.

### DESCRIPTION OF THE INVENTIONS

As used herein, halide designates a halogen atom attached to another atom (i.e. —F, —Cl, —Br, —I), alkyl refers to saturated hydrocarbon groups which can be linear or branched (e.g. methyl, ethyl, propyl, isopropyl, tert-butyl and the like), alkylene refers to a saturated hydrocarbon moiety with two attachment points which may be linear or branched (e.g. methylene (—CH₂—), ethylene (—CH₂—CH₂—), 1-methyl-ethylene (—CH(CH₃)—CH₂—), 1,1-di-methyl-ethylene (—C(CH₃)₂—CH₂—), propylene (—CH₂—CH₂—CH₂—), 2-methyl propylene (—CH₂—CH(CH₃)—CH₂—), and the like), cycloalkyl refers to a hydrocarbon containing one saturated cycle (e.g. cyclohexyl, cyclopropyl, cyclopentyl and the like), fluoroalkyl refers to a linear or branched saturated alkyl group in which all the hydrogens have been replaced by fluorine, cyclofluoroalkyl refers to a cycloalkyl group in which all the hydrogens have been replaced by fluorine. As used herein, the term “aryl” refers to refers to any functional group or substituent derived from an aromatic ring, such as phenyl, naphthyl, anthracyl, thienyl, indolyl etc. The aryl moiety may be unsubstituted containing only hydrogen, or may have one or more substituents chosen from a C₁-C₈ alkyl, a C₁-C₈ alkyloxy, a C₁-C₈ fluorinated alkyl, a C₃-C₈ branched alkyl, a C₃-C₈ branched fluoroalkyl, a C₃-C₈ cycloalkyl, a C₃-C₈ cyclofluoroalkyl, or a halide. The term vinyl aryl or vinyl aryl compound refers to an aryl moiety substituted with a vinyl group (—CH═CH₂). The vinyl group may be substituted with a C₁-C₄ alkyl or a C₁-C₄ fluoro alkyl. The term “poly(vinyl aryl)” refers to a polymer of a vinyl aryl monomer in which the vinyl group has polymerized to form the backbone of the polymer. This term refers to a homopolymer of a single vinyl aryl monomer or a random copolymer having two or more different vinyl aryl monomers. The terms “hydrophobic poly(vinyl aryl) brush precursor” refers to a hydrophobic poly(vinyl aryl) polymer which is terminated at one chain end by a reactive functional group which is capable of grafting on a substrate surface, thus attaching the polymer chain at on end to the substrate surface and forming a “brush” layer. The term “vinyl nitrogen heterocylic aryl” refers to a monomer containing a heterocylic aryl group containing at least one nitrogen atom in its ring and which has also a vinyl group attached to a carbon atom on the ring. This heterocyclic aryl group may be a derivative of the aryl moieties described above in which the aromatic ring contains at least one nitrogen atom; non limiting examples are 4-vinyl-pyridine, 3-vinyl-quinoline and the like. The term “-b-” refers to “-block-” and designates monomer repeat units that form block copolymer, for instance poly(vinyl aryl-b-alkyl methacrylate) refers to poly(vinyl aryl-block-alkyl methacrylate) which designates a block copolymer of a vinyl aryl compound with an alkyl methacrylate.

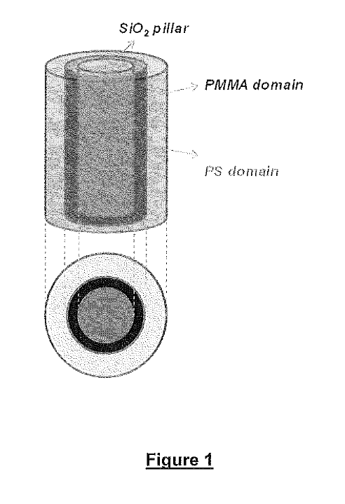

When using an array of pillars on a substrate as guide for via formation into the substrate in a Graphoepitaxy approach employing a diblock copolymer comprised of a highly etchable hydrophilic block and an etch resistant hydrophobic block, highly etchable hydrophobic block domains are formed at the center between a regular array of pillars arranged in a triangular or square array. However, because the highly etchable block also shows a preference for the surface of the pillars, highly etchable domain layer will also self-assemble surrounding these pillars. FIG. 1 illustrates this problem using a non-limiting example of a diblock copolymer of methyl methacrylate (MMA) and polystyrene (STY) (poly(STY-b-MMA) where it can be seen that the highly etchable poly(methyl methacrylate) (PMMA) hydrophilic block domains orient themselves around the hydrophilic pillar. During development with either a plasma etch or a wet chemical developer, defects will form due to the accumulation of highly etchable domains around the hydrophilic pillars. This arises because the more etchable hydrophilic domains (e.g PMMA domains) are more easily removed during either a wet chemical etch (e.g acetic acid and isopropyl alcohol) or an oxygen based dry plasma etch which create voids near the pillars used in this type of directed self-assembly aimed at forming a via array. Although FIG. 1 employs a specific diblock copolymer, it is illustrative of this problem in general which will occur whenever a diblock copolymer containing hydrophobic etch resistant block and hydrophilic highly etchable block come into contact with a hydrophilic pillar array to induce a via array by graphoepitaxy. Therefore there is a need for inventive processes and compositions to solve the new problem of this defect formation.

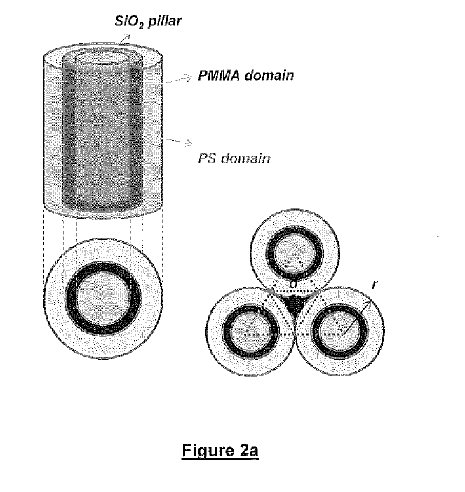

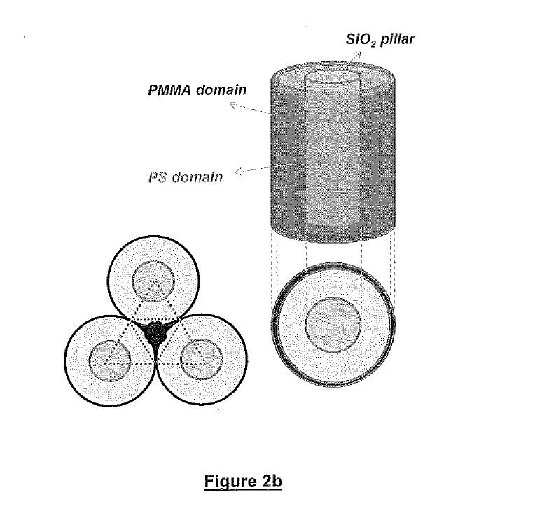

FIGS. 2a and 2b, using the non-limiting example poly(STY-b-MMA) diblock polymer compares respectively the situation which arises when the PMMA domains are present adjacent to the pillars to the situation which arises when, by employing the inventive processes of this invention, the etch resistant polystyrene (PSTY) domains of the block copolymer are made to arrange themselves around the pillar due to the attachment of hydrophobic brush grafted to the surface of the pillars by employing a poly(vinyl aryl) polymer terminated at one end by a reactive functional group. As seen in the cross section of the pillars in FIG. 2a, a ring of PMMA domains surrounds the pillar in the pillar array which can form a defect (depicted as “d”). When the PMMA domains are removed during either dry (e.g. oxygen plasma) or wet development, this area is removed forming large voids between the pillars in the pillar array. In contrast, as depicted in FIG. 2b, when the hydrophobic poly(vinyl aryl) brush precursor is grafted to the surface of the pillars, the hydrophobic etch resistant PSTY domains are adjacent to the pillars, and pattern transfer with either wet or dry development results in the clean formation of the vias as denoted by the circular area in the middle of the array formed by the three pillars in FIG. 2b.

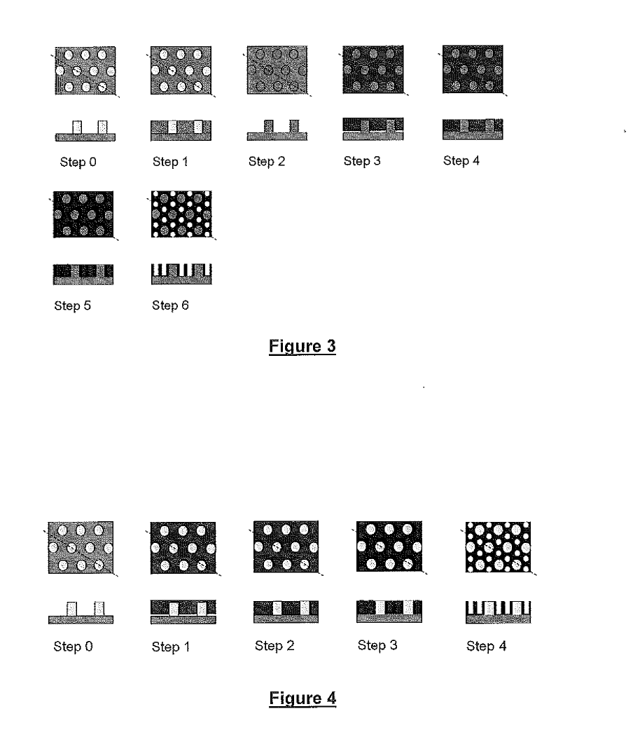

FIGS. 3 and 4 illustrate the two inventive processes for solving the defect problem pertinent to this application, in which a via array is made from an array of hydrophilic pillars by using different processes in which a hydrophobic poly(vinyl aryl) brush is grafted on the surface of the hydrophilic pillars. In these Figures, in each step, a top view of the pattern and a cross section as designated by the dashed line in the top view are presented. This grafting affects the direct self-assembly of a block copolymer comprised of a hydrophobic etch resistant block and a hydrophilic highly etchable block in which the etch resistant hydrophobic block domains of the diblock copolymer orient themselves around the pillars, thus allowing for the formation of an array of vias in which the vias are derived from the removal of the highly etchable hydrophilic domains by using either a wet chemical etch or a dry plasma etch.

FIG. 3 illustrates the graphoepitaxy “Dual Coating Process,” in which the poly(vinyl aryl) brush precursor and the block copolymer are coated in separate steps using two separate solutions. In this approach, in a first step, planar thin film of the poly(vinyl aryl) brush precursor is coated over an original regular array of pillars; in a second step this coating is baked, and any non-grafted poly(vinyl aryl) brush precursor is subsequently removed using a solvent, thus forming a hydrophobic brush coating on the pillars; in a third step a diblock copolymer is coated over this brush functionalized pillar array; in a fourth step a flow bake is applied to this coating to conformably fill the topography of the pillar array; in a fifth step an annealing bake is applied to the conformal coating to affect directed self-assembly to orient the domains of the block copolymer; in a sixth step the self-assembled structure is etched either with a chemical etchant or a plasma etchant to selectively remove the highly etchable hydrophilic block domains to form an array of vias.

FIG. 4 illustrates the graphoepitaxy “Single Coating Process” process where both the poly(vinyl aryl) brush precursor and the block copolymer are coated in a single step from a solution containing both components. In this novel “Single Coating Process” a novel composition is also be employed, which affects a faster and more effective grafting of the brush on the substrate surface. This novel composition is comprised of a the diblock copolymer, and a poly(vinyl aryl) brush precursor, a solvent and a thermal acid generator. This novel composition when used in the “Single Coating Process” has the unexpected advantage of forming a more effective grated brush layer.

In both novel processes and in the novel composition described above, a block copolymer is employed. Specific non-limiting examples of block copolymers that are useful for graphoepitaxy employing original regular array of pillars are any di block copolymers which can form domains through self-assembly and are comprised of a hydrophobic block resistant to chemical or plasma etch and a hydrophilic block which is highly etchable by either a chemical or plasma etch. The microdomains are formed by blocks of the same type which tend to self-associate. Thus the hydrophilic highly etchable block will self-associate to form one type of domain while the hydrophobic etch resistant blocks will self-associate to form another type of domain. Typically, block copolymer employed for this purpose are polymers in which the repeat units derived from monomers are arranged in blocks which are different compositionally, structurally or both and are capable of phase separating and forming domains. The blocks have differing chemical, photochemical properties enabling wet etching or differing plasma etch resistance enabling plasma etching. These differing properties are used to remove one block while keeping the other block intact on the surface, thus providing a pattern on the surface. Thus, the block may be selectively removed by plasma etching, solvent etching, developer etching using aqueous alkaline solution, etc.

For instance, in diblock copolymers based on organic monomers, one block can be made from polyolefinic monomers including polydienes, polyethers including poly(alkylene oxides) such as polyethylene oxide), polypropylene oxide), polybutylene oxide) or mixtures thereof; and on the other hand the other block can be made from plasma resistant monomers forming a block comprised of polyvinyaryls, polyvinyl nitrogen heterocylic aryl)'s, polyarylesters, or polyorganomoieties containing refractory elements.

Examples of polymer blocks susceptible to chemical wet etch are ones comprised of repeat unit whose chemical structure makes the polymer chain labile towards irradiation with UV, vacuum ultraviolet, extreme ultraviolet or e-beam; chemical structure of the polymer makes it labile towards these types of radiation which results in these polymer blocks being fragmented into small molecules such that these fragments may be removed by wet development with either an organic developer or an aqueous developer. Non-limiting examples are polymer blocks derived from repeat units such as alkyl vinyl sulfones (e.g. block made of 2-methylpentene sulfone repeat units), alkyl α-alkylacrylates, alkyl α-cyanoacrylates (e.g. methyl α-cyanoacrylate), alkyl α-haloacrylates (e.g. methyl α-chloroacrylate, or methyl α-bromoacrylate), alkyl methacrylates, α-alkylacrylic acid (e.g. methacrylic acid) or other similar block based on other vinyl repeat units whose polymer chains are susceptible to cleavage by irradiation with UV, vacuum ultraviolet, extreme ultraviolet or e-beam. A specific non-limiting example of a block copolymer containing a such a block susceptible to chemical wet etch is poly(styrene-b-methyl methacrylate).

Specific examples of highly plasma etchable blocks are those that can be derived from (meth)acrylate monomers such as (meth)acrylate, methyl (meth)acrylate, ethyl (meth)acrylate, n-propyl (meth)acrylate, isopropyl (meth)acrylate, n-butyl (meth)acrylate, isobutyl (meth)acrylate, n-pentyl (meth)acrylate, isopentyl (meth)acrylate, neopentyl (meth)acrylate, n-hexyl (meth)acrylate, cyclohexyl (meth)acrylate, isobornyl (meth)acrylate, hydroxyethyl (meth)acrylate or those derived from olefinic monomers such as ethylene, propylene, 1-butene, 1,3-butadiene, isoprene, dihydropyran, norbornene, maleic anhydride, or other similar highly plasma etchable moieties.

Specific examples of monomers which can form plasma resistant blocks are C₂₋₃₀ olefins or (meth)acrylate monomers containing refractory inorganic moieties including those based on Si, Ge, Ti, Fe, Al, and also blocks derived from a vinyl aryl monomers or vinyl nitrogen heterocylic aryl compounds; specific examples are blocks derived from monomers such as styrene, 4-vinylpyridine, 4-hydroxy styrene, 4-acetoxy styrene, 4-methylstyrene, alpha-methylstyrene.

A specific example of a suitable diblock copolymer containing a high etch resistant block and a highly etchable block would be the block copolymer poly(styrene-b-methyl methacrylate).

Other specific non-limiting examples of other diblock copolymers that are useful for graphoepitaxy employing an original regular array of pillars are poly(styrene-b-butadiene), poly(styrene-b-isoprene), poly(styrene-b-methyl methacrylate), poly(styrene-b-alkenyl aromatics), poly(styrene-b-(ethylene-propylene)), poly(styrene-b-t-butyl (meth)acrylate), poly(styrene-b-tetrahydrofuran), poly(styrene-b-ethyleneoxide), poly(styrene-b-dimethylsiloxane), poly(methyl methacrylate-b-dimethylsiloxane), and poly(methyl methacrylate-b-4-vinylpyridine)). All these polymeric materials share in common the presence of at least one block which is rich in repeat units resistant to plasma etching techniques typically employed in manufacturing IC devices, and at least one block which etches rapidly under these same conditions or that can be removed by chemical or photochemical processes This allows for the directed self-assembled polymer to pattern transfer onto the substrate to affect via formation.

Typically, the block copolymers have a weight-averaged molecular weight (M_{w}) in the range of about 3,000 to about 500,000 g/mol and a number averaged molecular weight (Mₙ) of about 1,000 to about 60,000 and a polydispersity (M_{w}/Mₙ) (PD) of about 1.01 to about 6, or 1.01 to about 2 or 1.01 to about 1.5. Molecular weight, both M_{w} and Mₙ, can be determined by, for example, gel permeation chromatography using a universal calibration method, calibrated to polystyrene standards. This ensures that the polymer blocks have enough mobility to undergo self-assembly when applied to a given surface either spontaneously, or by using a purely thermal treatment, or through a thermal process which is assisted by the absorption of solvent vapor into the polymer framework to increase flow of segments enabling self-assembly to occur.

Solvents suitable for dissolving either the block copolymers alone or in a composition with other components include propylene glycol monomethyl ether acetate (PGMEA), ethoxyethyl propionate, anisole, ethyl lactate, 2-heptanone, cyclohexanone, amyl acetate, n-butyl acetate, n-amyl ketone (MAK), gamma-butyrolactone (GBL), toluene, and the like. In an embodiment, specifically useful casting solvents include propylene glycol monomethyl ether acetate (PGMEA), gamma-butyrolactone (GBL), or a combination of these solvents.

Solutions containing the block copolymer can further comprise additional components and/or additives selected from the group consisting of: inorganic-containing polymers; additives including small molecules, inorganic-containing molecules, surfactants, photoacid generators, thermal acid generators, quenchers, hardeners, cross-linkers, chain extenders, and the like; and combinations comprising at least one of the foregoing, wherein one or more of the additional components and/or additives co-assemble with the block copolymer to form the block copolymer assembly.

The polymer brush precursor used in the present inventions to graft to the original array of pillars on the substrate and described herein can be a poly(vinyl aryl) brush precursor which is a hydrophobic polymer brush precursor comprised of vinyl aryl repeat units where the polymer is terminated at one chain end by a reactive functional group chosen from the group consisting of hydroxyl (—OH), amino (—NH₂), phosphonic acid (—P═O(OH)₂) and phosphonic acid alkyl ester —P═O(OR)₂, where R is a C₁-C₄ alkyl group and further where when coated as a thin film this polymer has a contact angle with water of about 75° to about 90°. In some embodiments of the present inventions this poly(vinyl aryl) brush precursor is a poly(vinyl aryl) homopolymer with the terminal group of a reactive functional group. In other embodiments of the present inventions the poly(vinyl aryl) brush precursor has a Mw between 1,000 and 100,000. In these embodiments a polydispersity of 3 to 1 is preferred; polydispersity from 1.2 to 1.0 is another embodiment.

In another embodiment of these inventions the hydrophobic polymer brush precursor has a contact angle with water of about 80° to about 90°.

In one embodiment the hydrophobic polymer brush precursor comprising vinyl aryl repeat units terminated at one end by a reactive functional group has structure (1),

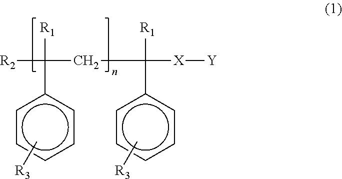

wherein R₁ is independently hydrogen, C₁-C₄ alkyl, or C₁-C₄ fluorinated alkyl, R₂ is hydrogen, a C₁-C₄ alkyl, a C₃-C₈ branched alkyl, an alkyl nitroxide group having structure (2), or an azo end group having structure (3), where R₄, R₅ and R₆ are independently C₁-C₈ alkyl or C₃-C₈ branched alkyl, and further where R₄ and R₅ may be joined by a covalent bond forming a ring, R₃ is hydrogen, a C₁-C₈ alkyl, a C₁-C₈ alkyloxy, a C₁-C₈ fluorinated alkyl, a C₃-C₈ branched alkyl, a C₃-C₈ branched fluoroalkyl, a C₃-C₈ cycloalkyl, a C₃-C₈ cyclofluoroalkyl, or a halide, and X is a C₁-C₁₂ alkylene spacer moiety or a cyano substituted alkylene spacer moiety where X=—C(R₇)(CN)-(A₁)-A₂-(A₃)- and where R₇ is C₁-C₈ alkyl group, A₁ and A₃ are C₁-C₈ alkylene moities, and A₂ is direct bond or a heteroatom containing spacer moiety chosen from amide (—NH—C═O—) or (—C═O—NH—), ester (—O—C═O—) or (—C═O—O—), or ether (—O—); and further where Y is a functional group chosen from the group consisting of hydroxyl (—OH), amino (—NH₂), phosphonic acid (—P═O(OH)₂) and phosphonic acid alkyl ester —P═O(OR)₂, where R is a C₁-C₄ alkyl group and n represents the number of repeat units in the polymer.

A more specific embodiment of the hydrophobic polymer brush precursor is where in structure (1) R₁ is hydrogen, R₂ is a nitroxide group having structure (2), R₃ is hydrogen, X is —CH₂—, and Y is OH. Another more specific embodiment is where in structure (1) R1 hydrogen, R₃ is hydrogen, X—Y is —CH(CH₃)(CN)—CH₂—CH₂—C═O—NH—CH₂—CH₂—P═O(OCH₃)₂ or —CH(CH₃)(CN)—CH₂—CH₂—C═O—NH—CH₂—CH₂—P═O(OH)₂.

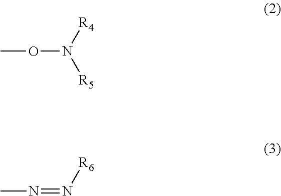

In the “Dual Coating Process” the solution of poly(vinyl aryl) brush precursor is made in any useful casting solvent and may specifically be selected from the group consisting of propylene glycol methyl ether acetate, n-butyl acetate, gamma-butyrolactione, anisol, 2-heptanone, xylene, anisole, decalin, cyclohexane, cyclohexene, methylcyclohexane, ethylcyclohexane, limonene, hexane, octane, nonane, decane, and mixtures of these.

In the “dual coating process” the “single coat process” and the novel composition when a thermal acid generator component is employed in solution containing hydrophobic polymer brush precursor it is chosen from o-nitrobenzyl esters of sulfonic acid, p-nitrobenzyl esters of sulfonic acids, 5-norbomene-2,3-dicarboximidyl-N-esters of sulfonic acid, dicarboximidyl esters of sulfonic acid, oxime sulfonates, ammonium salts of primary amines and a sulfonic acid, ammonium salts of secondary amines and a sulfonic acid, ammonium salts of a tertiary amine and a sulfonic acid or mixtures of these.

In the “Single Coating Process” and “Dual Coating Process,” and the novel composition for making multiple vias, the solutions containing either the block copolymer and/or the poly(vinyl aryl) brush precursor may, apart from the solvent, also contain additional optional components selected from inorganic-containing polymers; additives including small molecules, inorganic-containing molecules, surfactants, photoacid generators, thermal acid generators, quenchers, hardeners, cross-linkers, chain extenders, and the like; and combinations comprising at least one of the foregoing.

The original regular array of hydrophilic pillars formed on a substrate and useful for this invention are those in which pillars have diameters of about 40 to about 100 nm with a height of about 50 to about 200 nm. These pillars are arranged in a regular hexagonal, square, triangular or rectangular array in which the pillars are about 40 to about 100 nm from each other. The hydrophilic pillars are comprised of a material chosen from the group consisting of SiO₂, SiN, SiON, Si, Al, W, Mo, Cr, Cu, resist, and a spin on high carbon underlayer material.

In the present invention the original pillar array may be formed by using either a negative or positive photoresist using either positive tone or negative tone development processes, and imageable using any conventional lithographic techniques, such as e-beam, ion beam, x-ray, EUV (13.5 nm), broadband, or UV (450 nm-10 nm) exposure, immersion lithography, etc. In one embodiment the present invention is particularly useful for 193 nm imagewise exposure using either dry lithography or immersion lithography. For 193 nm lithography, a commercially available positive 193 nm photoresist can be employed such as the non-limiting example of AZ AX2110P (available from AZ Electronic Materials USA Corp, Somerville, N.J.), photoresists from Shin-Etsu Chemical Corp (Asahi Seimei Otemachi Bldg., 6-1, Ohtemachi 2-chome, Chiyoda-ku, Tokyo 100-0004, Japan) JSR Micro Inc. (1280 N Mathilda Ave, Sunnyvale, Calif. 94089), and other photoresists available from FujiFilm (FUJIFILM Electronic Materials U.S.A., Inc. 80 Circuit Drive North Kingstown, R.I. 02852), TOK (TOKYO OHKA KOGYO AMERICA, INC 190 Topaz Street Milpitas, Calif. 95035, U.S.A.), etc. These photoresists may be developed after exposure and post exposure bake using an aqueous alkaline developer comprising tetramethylammonium hydroxide to give a positive tone pattern, or developed using an organic solvent such as n-amyl ketone (MAK), n-butyl acetate, anisole, etc. to give a negative tone pattern. Alternatively, also for 193 nm exposure, commercially available negative tone photoresists may be employed.

In both the “Single Coating Process” and “Dual Coat Process” solutions of block copolymers or poly(vinyl aryl) brush precursor or a mixture containing both of these may be applied to a substrate containing an original regular array of pillars by normal spin coating techniques. After applying a film from the block copolymer containing solution in either of these processes, a flow bake is needed for the coating material to conformally fill the substrate with the pillar array. The temperature of this flow bake is between about 100° C. and about 160° C. In the “Single Coating Approach” this bake also allows for grafting of the hydrophobic polymer brush precursor. After the flow bake, an annealing bake is employed to allow for the self-assembly of the block copolymer by graphoepitaxy directed by the pillar array which is now coated by the hydrophobic polymer brush. This annealing may be done in air at a bake temperature between about 180° C. to about 250° C., for 60 to 1000 seconds. The annealing bake can also be done in nitrogen at a temperature 180° C. and 300° C. for 60 to 1000 seconds.

In order to remove the self-assembled copolymer domains containing the more highly etchable block copolymer units, a standard plasma etch process, such as a plasma comprising oxygen may be used; additionally argon, carbon monoxide, carbon dioxide, SF₆, CF₄, CHF₃, Cl₂, or Br₂ may also be present in the plasma.

Alternatively, radiation is employed to affect selective bond cleavage of these domains containing the more highly etchable block copolymer units. This radiation can be any radiation of sufficient energy to cleave the repeating units domains comprised of highly etchable repeating units of the block copolymer. Examples are ultraviolet (UV) (400-10 nm) vacuum ultraviolet radiation (200-10 nm) (e.g. 172 nm), electron beams, particle beams, extreme ultraviolet (EUV) (121-10 nm) (e.g. 13.5 nm), x-ray and the like. After cleavage of these oriented domains containing the more etchable repeat unit, the block copolymers are removed by solvent etching. Solvents which may be employed include C₁-C₄ alkyl alcohols, C₁-C₄ alkylcarboxylic acid or a mixtures of these. Specific examples of suitable solvents are as follows: acetic acid, ethyl alcohol, isopropyl alcohol and their mixtures.

In either case the remaining highly etch resistant oriented domains will define an array of via's in this coating where the highly etchable oriented polymer block domains have been removed by either dry or wet etching, as described above. This array of via's may be employed to etch a corresponding via array into the substrate itself by using either a dry plasma etching or a wet chemical etching suitable for the substrate. As an example of a dry plasma, fluorine based plasma may be used to etch into a silicon oxide, Silicon Nitride, SiliconOxyNitride, or Polysilicon substrates.

The following describes in detail the novel Dual Coating Process and the novel Single Coating Process and the novel composition useful for the Single Coating Process.

The novel Dual Coating Process is a process for making multiple via's from an original regular array of hydrophilic pillars formed on a substrate comprising steps i) to vii);

i) forming a coating of a planar thin film over an original regular array of hydrophilic pillars formed on a substrate from a first coating solution comprising a hydrophobic polymer brush precursor, where the hydrophobic polymer brush precursor comprises vinyl aryl repeat units and further where the polymer is terminated at one chain end with a reactive functional group chosen from the group consisting of hydroxyl (—OH), amino (—NH₂), phosphonic acid (—P═O(OH)₂) and phosphonic acid alkyl ester —P═O(OR)₂, where R is a C₁-C₄ alkyl group, and further where the planar thin film has a contact angle with water of about 75° to about 90°;

ii) baking the planar thin film, so as to graft the reactive functional group terminated chain end of the hydrophobic polymer brush precursor to the hydrophilic surface on the pillars thus forming a hydrophobic coating on the pillars;

iii) removing the non-grafted hydrophobic polymer brush precursor with a solvent composition;

iv) coating the hydrophobic coated pillars with a second coating solution comprising a block copolymer such that the second coating film is conformal, wherein the block copolymer comprises a hydrophobic etch resistant block and a hydrophilic highly etchable block;

v) applying a flow bake to the second coating film so as to conformably fill the topography of the pillar array;

vi) applying an annealing bake to cause self-assembly of the block copolymer of the second coating film to form self-assembled polymeric block domains, wherein the hydrophophic etch resistant blocks domains of the block copolymer attach to the hydrophobic coating on the pillars; and,
vii) developing the self-assembled polymeric block domains to form the final regular via array.

In another embodiment of the Double Coat Process in step i) the hydrophobic polymer brush precursor has a contact angle with water between about 80° to about 90°.

A further embodiment of the above process is where the regular array is a hexagonal, square, triangular or rectangular array. Another embodiment of this inventive process is where the hydrophobic polymer brush precursor of the first coating solution is a poly(vinyl aryl) homopolymer. Another embodiment of this inventive process is where the hydrophobic polymer brush precursor of the first coating has a Mw between 1,000 and 100,000. In this embodiment a polydispersity of 3 to 1 is preferred. A polydispersity 1.2 to 1.0 is another embodiment.

In still another embodiment, the hydrophobic polymer brush precursor of the first coating has structure (1)

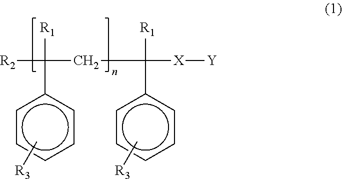

wherein R₁ is independently hydrogen, a C₁-C₄ alkyl, or a C₁-C₄ fluorinated alkyl, R₂ is hydrogen, a C₁-C₄ alkyl, a C₃-C₈ branched, an alkyl nitroxide group having structure (2), or a azo end group having structure (3) where R₄, R₅ and R₆ are independently C₁-C₈ alkyl or C₃-C₈ branched alkyl and further where R₄ and R₅ may be joined by a convalent bond forming a ring, R₃ is hydrogen, a C₁-C₈ alkyl, a C₁-C₈ alkyloxy, a C₁-C₈ fluorinated alkyl, a C₃-C₈ branched alkyl, a C₃-C₈ branched fluoroalkyl, a C₃-C₈ cycloalkyl, a C₃-C₈ cyclofluoroalkyl, or a halide, and X is a C₁-C₁₂ alkylene spacer moiety or a cyano substituted alkylene spacer moiety where X=—C(R₇)(CN)-(A₁)-A₂-(A₃)- and where R₇ is C₁-C₈ alkyl group, A₁ and A₃ are C₁-C₈ alkylene moieties, and A₂ is direct bond or a heteroatom containing spacer moiety chosen from amide (—NH—C═O—) or (—C═O—NH—), ester (—O—C═O—) or (—C═O—O—), or ether (—O—); and further where Y is a functional group chosen from the group consisting of hydroxyl (—OH), amino (—NH₂), phosphonic acid (—P═O(OH)₂) and phosphonic acid alkyl ester —P═O(OR)₂, where R is a C₁-C₄ alkyl group and n represents the number of repeat units in the polymer.

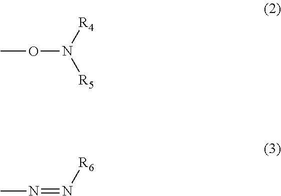

A more specific embodiment of the Dual Coat Process is where in structure (1) R₁ is hydrogen, R₂ is a nitroxide group having structure (2), R₃ is hydrogen, X is —CH₂—, and Y is OH. Another more specific embodiment of the Dual Coat Process is where in structure (1) R1 hydrogen R₃ is hydrogen, X—Y is —CH(CH₃)(CN)—CH₂—CH₂—C═O—NH—CH₂—CH₂—P═O(OCH₃)₂ or —CH(CH₃)(CN)—CH₂—CH₂—C═O—NH—CH₂—CH₂—P═O(OH)₂.

Another aspect of the Dual Coating Process is wherein in step i) the concentration of the a hydrophobic polymer brush precursor comprised of vinyl aryl repeat units where the polymer is terminated at one chain end by a reactive functional group is between 0.1 to 10 wt %.

Another aspect of the Dual Coating Process is wherein in step i) when first coating solution is further comprised of a thermal acid generator. The thermal acid generator can be present in first coating solution in an amount corresponding to about 1 to 30% of the total weight of the hydrophobic polymer brush precursor present in this first coating solution. More specifically, in this aspect of this invention, the thermal acid generator may be present from 5 to 20% of the weight of the hydrophobic polymeric brush precursor. The thermal acid generator component employed is chosen from o-nitrobenzyl esters of sulfonic acid, p-nitrobenzyl esters of sulfonic acids, 5-norbornene-2,3-dicarboximidyl-N-esters of sulfonic acid, dicarboximidyl esters of sulfonic acid, oxime sulfonates, ammonium salts of primary amines and a sulfonic acid, ammonium salts of secondary amines and a sulfonic acid, ammonium salts of a tertiary amine and a sulfonic acid or mixtures of these. A specific embodiment of the first coating solution is where the thermal acid generator is p-nitrobenzyl ester of a sulfonic acid. A further specific example is where the thermal acid generator is p-nitrobenzyl tosylate.

A further embodiment of the Dual Coating Process is where in step iv the second coating solution contains a concentration of between 0.5 to 5 wt % of a block copolymer in a solvent.

Another aspect of the Dual Coating Process is where in step i) and iii) the solvent is selected from the group consisting of propylene glycol methyl ether acetate, n-butyl acetate, gamma-butyrolactione, anisol, 2-heptanone, xylene, anisole, decalin, cyclohexane, cyclohexene, methylcyclohexane, ethylcyclohexane, limonene, hexane, octane, nonane, decane, and mixtures of these.

A further embodiment of the Dual Coating Process is where the original regular array of hydrophilic pillars is comprised of a material chosen from the group consisting of SiO₂, SiN, SiON, Si, Al, W, Mo, Cr, Cu, photoresist, and a spin on high carbon underlayer material.

Another embodiment of the Dual Coating Process is where in step iv) the block copolymer is the block copolymer of an alkyl methacrylate with a vinyl aryl compound [poly(alkyl methacrylate-block-vinyl aryl compound)], an alkyl acrylate with a vinyl aryl compound [poly(alkyl acrylate-block-vinyl aryl compound)], an alkyl methacrylate with a vinyl nitrogen heterocylic aryl compound [poly(alkyl acrylate-block-vinyl nitrogen heterocylic aryl compound)] or a block copolymer of alkyl acrylate with a vinyl nitrogen heterocylic aryl compound [poly(alkyl acrylate-block-vinyl nitrogen heterocylic aryl compound)]. A further more specific aspect of this process is where in step iv) the block copolymer is an methyl methacrylate styrene block copolymer [poly(styrene-block-methyl methacrylate)]. Another aspect of this process is wherein in step iv) the block copolymer is a block copolymer of methyl methacrylate and 4-vinylpyridine[poly(methyl methacrylate-block-4-vinylpyridine)].

A further embodiment of the Dual Coating Process is wherein in step iv) the solvent for the second coating solution is comprised of any hydrocarbon solvent such as a ketone (e.g. 2-heptanone(MAK), Methyl isobutyl ketone(MJBK), cylcopentanone, cycloheptanone), an ether (eg Dibutylether), an ester (e.g. butyl acetate), an ester ether and mixtures thereof. In a further embodiment the block copolymer solvent is comprised of a mixture of a 1,2-propanediol alkyl ether alkylcarboxylate and an alkyl alkylcarboxylate wherein the alkyl moieties are chosen independently from C₁-C₄ alkyl moieties. A more specific aspect of this is where the solvent for the block copolymer is a mixture of propylene glycol methylether acetate (PGMEA) and n-butyl acetate (n-BA). A still more specific aspect of this is where the content of the mixture of PGMEA and n-BA, the n-BA ranges between 10 and 30 wt %.

Another embodiment of the Dual Coating Process is where in step iv) the flow bake is between 100° C. and 160° C. A further embodiment of this process invention is wherein in step v) the annealing bake is between 180° C. and 250° C. and is done in air. In another embodiment of this process invention in step v) the annealing bake is between 180° C. and 300° C. and is also done in nitrogen.

In a further embodiment of the Dual Coating Process after step vi) a flood exposure with radiation is employed to break bounds in the self-assembled structures, a further embodiment of this aspect is where the radiation is vacuum ultraviolet (VUV) having a wavelength of 172 nm. In another embodiment of this aspect of this the self-assembled structure exposed to radiation is wet developed with an alkyl alcohol, a alkylcarboxylic acid or a mixtures of these wherein the alkyl moieties are chosen independently from C₁-C₄ alkyl moieties.

Another embodiment of the Dual Coating Process is in step vii) the self-assembled structure is dry developed using a plasma comprised of oxygen or a mixture of oxygen with a halogen.

The second inventive process for making new multiple via's from an original regular array of hydrophilic pillars, is a Single Coat Process, comprising the steps of;

i) forming a coating film on the original regular array of hydrophilic pillars on a substrate from a third coating solution such than the coating film is of sufficient thickness to cover the pillars, wherein the third coating solution comprises, a hydrophobic polymer brush precursor, (where the hydrophobic polymer brush precursor, if coated in a thin film by itself, has a contact angle with water of about 75° to about 90°);

a block copolymer and a solvent, further where the hydrophobic polymer brush precursor comprises vinyl aryl repeat units and further where the hydrophobic polymer brush precursor is terminated at one chain end with a reactive functional group chosen from the group consisting of hydroxyl (—OH), amino (—NH₂), phosphonic acid (—P═O(OH)₂) and phosphonic acid alkyl ester —P═O(OR)₂, where R is a C₁-C₄ alkyl group, and further wherein the block copolymer comprises a hydrophobic etch resistant block and a highly etchable hydrophilic block;

ii) applying a grafting bake so as to graft the reactive functional group terminated chain end of the hydrophobic polymer brush precursor to the hydrophilic surface of the coated pillars thus forming a hydrophobic surface on the pillars;

iii) applying an annealing bake to cause self-assembly of the block copolymer, where the hydrophophic etch resistant blocks of the block copolymer attach to the original pillars with the hydrophobic surface; and,
iv) developing the self-assembled polymeric structure to form a final regular via array.

In another embodiment of the Single Coat Process in step 1) the hydrophobic polymer brush precursor has a contact angle with water between about 80° and about 90°.

A further embodiment of Single Coat Process is where the original regular pillar array is a hexagonal, square, triangular or rectangular array. Another embodiment of Single Coat Process is where the hydrophobic polymer brush precursor of the third coating is a poly(vinyl aryl) homopolymer. Another embodiment of Single Coat Process is where the hydrophobic polymer brush precursor of the third coating has a Mw between 1,000 and 100,000. In this embodiment a polydispersity of 3 or smaller is preferred. A polydispersity less than 1.2 is another embodiment.

A further embodiment of Single Coat Process is where in the third coating solution the hydrophobic polymer brush precursor comprises between 1 to 30 wt % of the total solids and further where the block copolymer comprises between 70 wt % to 99 wt % of the total solids and where the third coating solution itself contains 0.5 to 5 wt % total solids. Another embodiment of Single Coat Process is where the third coating solution further comprises a thermal acid generator. The thermal acid generator can be present in the third coating solution in an amount corresponding to about 1 to about 30% of the total weight of the hydrophobic polymeric brush precursor itself present in this third coating solution. More specifically in this aspect of this invention the thermal acid generator may be present from 5 to 20% of the total weight of weight of the hydrophobic polymeric brush precursor. Another embodiment of this process is where the thermal acid generator is chosen from o-nitrobenzyl esters of sulfonic acid, p-nitrobenzyl esters of sulfonic acids, 5-norbornene-2,3-dicarboximidyl-N-esters of sulfonic acid, dicarboximidyl esters of sulfonic acid, oxime sulfonates, ammonium salts of primary amines and a sulfonic acid, ammonium salts of secondary amines and a sulfonic acid, ammonium salts of a tertiary amine and a sulfonic acid or mixtures of these. A specific embodiment of the third coating solution is where the thermal acid generator is p-nitrobenzyl ester of a sulfonic acid. A further specific example is where the thermal acid generator is p-nitrobenzyl tosylate.

Another embodiment of Single Coat Process is where the hydrophobic polymer brush precursor of the third coating solution has a reactive functional group of structure (1)

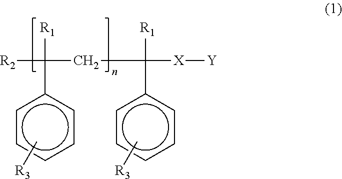

wherein R₁ is independently hydrogen, a C₁-C₄ alkyl, or a C₁-C₄ fluorinated alkyl, R₂ is hydrogen, a C₁-C₄ alkyl, a C₃-C₈ branched, an alkyl nitroxide group having structure (2), an azo end group having structure (3) where R₄, R₅ and R₆ are independently C₁-C₈ alkyl or C₃-C₈ branched alkyl and further where R₄ and R₅ may be joined by a convalent bond forming a ring, R₃ is hydrogen, a C₁-C₈ alkyl, a C₁-C₈ alkyloxy, a C₁-C₈ fluorinated alkyl, a C₃-C₈ branched alkyl, a C₃—C₈ branched fluoroalkyl, a C₃-C₈ cycloalkyl, a C₃-C₈ cyclofluoroalkyl, or a halide, and further where X is a C₁-C₁₂ alkylene spacer moiety or a cyano substituted alkylene spacer moiety where X=—C(R₇)(CN)-(A₁)-A₂-(A₃)- and where R₇ is C₁-C₈ alkyl group, A₁ and A₃ are C₁-C₆ alkylene moities, and A₂ is direct bond or a heteroatom containing spacer moiety chosen from amide (—NH—C═O—) or (—C═O—NH—), ester (—O—C═O—) or (—C═O—O—), or ether (—O—); and further where Y is a functional group chosen from the group consisting of hydroxyl (—OH), amino (—NH₂), phosphonic acid (—P═O(OH)₂) and phosphonic acid alkyl ester —P═O(OR)₂, where R is a C₁-C₄ alkyl group and n represents the number of repeat units in the polymer.

A more specific embodiment of the Single Coat Process is where in structure (1) R₁ is hydrogen, R₂ is a nitroxide group having structure (2), R₃ is hydrogen, X is —CH₂—, and Y is OH. Another more specific embodiment of the Single Coat Process is where in structure (1) R1 hydrogen R₃ is hydrogen, X—Y is —CH(CH₃)(CN)—CH₂—CH₂—C═O—NH—CH₂—CH₂—P═O(OCH₃)₂ or —CH(CH₃)(CN)—CH₂—CH₂—C═O—NH—CH₂—CH₂—P═O(OH)₂.

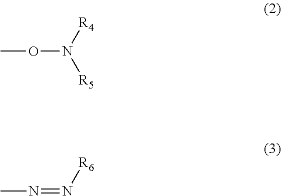

Another embodiment of the second inventive process is where the original regular pillar array is comprised of material chosen from the group consisting of SiO₂, SiN, SiON, Si, Al, W, Mo, Cr, Cu, resist, and a spin on high carbon underlayer material.

A further embodiment of the Single Coat Process is the block copolymer is a block copolymer of an alkyl methacrylate with a vinyl aryl compound [poly(alkyl methacrylate-block-vinyl aryl compound)], an alkyl acrylate with a vinyl aryl compound [poly(alkyl acrylate-block-vinyl aryl compound)], an alkyl methacrylate with a vinyl nitrogen heterocylic aryl compound [poly(alkyl acrylate-block-vinyl nitrogen heterocylic aryl compound)] or a block copolymer of alkyl acrylate with a vinyl nitrogen heterocylic aryl compound [poly(alkyl acrylate-block-vinyl nitrogen heterocylic aryl compound)]. A further more specific aspect of this process is wherein in step iv) the block copolymer is an methyl methacrylate and styrene block copolymer [poly(styrene-block-methyl methacrylate)]. Another aspect of this process is wherein in step iv) the block copolymer is a block copolymer of methyl methacrylate and 4-vinylpyridine[poly(methyl methacrylate-block-4-vinyl pyridine)].

A further embodiment of the second inventive process is where the third coating solution solvent is mixture of a 1,2-propanediol alkyl ether alkylcarboxylate and an alkyl alkylcarboxylate wherein the alkyl moieties may be chosen independently from C₁-C₄ alkyls. A more specific embodiment of this is when the coating solution is a mixture of propylene glycol methyl ether acetate (PGMEA) and n-butyl acetate (n-BuA). A still more specific aspect of this is where the content of the mixture of PGMEA and n-BA, the n-BA ranges between 10 and 30 wt % of the total solution.

Another aspect of Single Coat Process invention is where in step ii) the grafting bake is between 100° C. and 160° C. Another embodiment of the Single Coat Process is where in step iii) the annealing bake is between 180° C. and 250° C. and the annealing is done in air. Alternatively, in step iii) the annealing bake is between 180° C. and 300° C. and is done in nitrogen.

Another aspect of the Single Coat Process is in step iii) a flood exposure with radiation is employed to break bounds in the self-assembled polymeric structures. A more specific instance of this embodiment is when the radiation is vacuum ultraviolet (VUV) having a wavelength of 172 nm. In this embodiment when the self-assembled polymer structure is exposed to radiation it is wet developed with an alkyl alcohol, an alkyl carboxylic acid or a mixtures of these wherein the alkyl moieties are chosen independently from C₁-C₄ alkyl moieties.

Another aspect of the Single Coat Process is in step vi) the self-assembled polymeric structure is dry developed using a plasma comprised of oxygen or a mixture of oxygen with a halogen.

The present invention further relates to a novel third coating composition for making multiple via's from a regular array of hydrophilic pillars comprising;

i) a hydrophobic polymeric brush precursor comprising vinyl aryl repeat units where the hydrophobic polymeric brush precursor is terminated at one chain end by a functional group chosen from the group consisting of hydroxyl (—OH), amino (—NH₂), phosphonic acid (—P═O(OH)₂) and phosphonic acid alkyl ester —P═O(OR)₂, where R is a C₁-C₄ alkyl group, where the hydrophobic polymer brush precursor, if coated in a thin film by itself, and further has a contact angle with water of about 80° to about 90°;

ii) a block copolymer comprising a hydrophobic etch resistant block and a hydrophilic highly etchable block;

iii) a thermal acid generator; and,

iv) a solvent.

In another embodiment of the novel composition, the hydrophobic polymer brush precursor in i) has a contact angle with water between 80° and 90°.

In the novel composition, the hydrophobic polymer brush precursor terminated at one chain end by a functional group has structure (1)

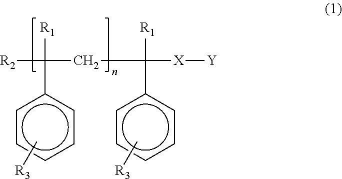

wherein R₁ is independently hydrogen, a C₁-C₄ alkyl, or a C₁-C₄ fluorinated alkyl, R₂ is hydrogen, a C₁-C₄ alkyl, a C₃-C₈ branched, an alkyl nitroxide group having structure (2), an azo end group having structure (3) where R₄, R₅ and R₆ are independently C₁-C₈ alkyl or C₃-C₈ branched alkyl and further where R₄ and R₅ may be joined by a convalent bond forming a ring, R₃ is hydrogen, a C₁-C₈ alkyl, a C₁-C₈ alkyloxy, a C₁-C₈ fluorinated alkyl, a C₃-C₈ branched alkyl, a C₃-C₈ branched fluoroalkyl, a C₃-C₈ cycloalkyl, a C₃-C₈ cyclofluoroalkyl, or a halide, and further where X is a C₁-C₁₂ alkylene spacer moiety or a cyano substituted alkylene spacer moiety where X=—C(R₇)(CN)-(A₁)-A₂-(A₃)- and where R₇ is C₁-C₈ alkyl group, A₁ and A₃ are C₁-C₆ alkylene moities, and A₂ is direct bond or a heteroatom containing spacer moiety chosen from amide (—NH—C═O—) or (—C═O—NH—), ester (—O—C═O—) or (—C═O—O—), or ether (—O—); and further where Y is a functional group chosen from the group consisting of hydroxyl (—OH), amino (—NH₂), phosphonic acid (—P═O(OH)₂) and phosphonic acid alkyl ester —P═O(OR)₂, where R is a C₁-C₄ alkyl group and n represents the number of repeat units in the polymer.

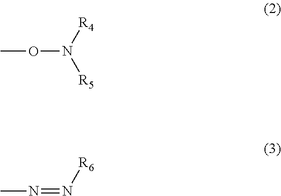

A more specific embodiment of the novel composition is where in structure (1) R₁ is hydrogen, R₂ is a nitroxide group having structure (2), R₃ is hydrogen, X is —CH₂—, and Y is OH. Another more specific embodiment of the Single Coat Process is where in structure (1) R1 hydrogen R₃ is hydrogen, and —X—Y is —CH(CH₃)(CN)—CH₂—CH₂—C═O—NH—CH₂—CH₂—P═O(OCH₃)₂ or —CH(CH₃)(CH₃)—CH₂—CH₂—C═O—NH—CH₂—CH₂—P═O(OH)₂.

In one embodiment of the novel composition the thermal acid generator is chosen from o-nitrobenzyl esters of sulfonic acid, p-nitrobenzyl esters of sulfonic acids, 5-norbornene-2,3-dicarboximidyl-N-esters of sulfonic acid, dicarboximidyl esters of sulfonic acid, oxime sulfonates, ammonium salts of primary amines and a sulfonic acid, ammonium salts of secondary amines and a sulfonic acid, ammonium salts of a tertiary amine and a sulfonic acid or mixtures of these. A more specific example of the embodiment is where the thermal acid generator is p-nitrobenzyl esters of sulfonic acid. A still more specific example of this embodiment is when the thermal acid generator is p-nitrobenzyl tosylate.

In one embodiment of this novel third coating composition the block copolymer is a methyl methacrylate and styrene.

A further embodiment of this novel composition is where this third coating composition the hydrophobic polymer brush precursor comprises between 1 to 30 wt % of the total solids and further where of the block copolymer comprises between 70 wt % to 99 wt % of the total solids and where the coating solution itself contains 0.5 to 5 wt % total solids in a solvent. Another embodiment of this second inventive process is where the third coating solution also comprises a thermal acid generator and where this component is present in an amount corresponding to about 1 to 30% of the total weight of the hydrophobic polymer brush precursor present in this third coating solution More specifically in this aspect of this invention the thermal acid generator may be present from 5 to 20% of the total weight of the hydrophobic polymeric brush precursor present in this third coating solution.

In one embodiment of this novel third coating composition the coating solution solvent is a mixture of a 1, 2-propanediol alkyl ether alkylcarboxylate and an alkyl alkylcarboxylate wherein the alkyl moieties may be chosen independently from C₁-C₄ alkyls. A more specific embodiment of this is when the coating solution is a mixture of propylene glycol methyl ether acetate (PGMEA) and n-butyl acetate (n-BuA). A still more specific aspect of this is where the content of the mixture of PGMEA and n-BA.

In one embodiment of the present novel composition the thermal acid generator may be omitted.

The following specific examples will provide detailed illustrations of the methods of producing and utilizing compositions of the present invention. These examples are not intended, however, to limit or restrict the scope of the invention in any way and should not be construed as providing conditions, parameters or values which must be utilized exclusively in order to practice the present invention.

### EXAMPLES

The molecular weight of the polymers was measured with a Gel Permeation Chromatograph. The hydroxyl terminated polystyrene brush precursor Mₙ 19 k polydispersity 1.15 was obtained from Polymer Source Inc. (124 Avro Street, Dorval (Montreal), Quebec, Canada). The poly(styrene-block-methyl methacrylate) Mw: 77 k, polysdisperisty 1.09 was obtained from. Polymer Source Inc. (124 Avro Street, Dorval (Montreal), Quebec, Canada). All other chemicals were obtained from the Aldrich Chemical Company (Sigma-Aldrich Corp St. Louis, Mo., USA). Lithographic Exposures were done with a Hamamatsu Photonics (250 Wood Avenue Middlesex, N.J. 08846), EX-mini. Etching Experiments were done with a Nordson March (300 Nordson Dr. M/S 47 Amherst, Ohio 44001 U.S.A.) RIE-1700. Spinning and development of films and patterns was done with a Litho Tech Japan (Litho Tech Japan Corporation 2-6-6-201 Namiki, Kawaguchi-shi, Saitama, 3320034, Japan), LARC1012 or a SOKUDO (5th Fl. K·I Shijo Building, 88 Kankoboko-cho, Shijodori-Muromachi-Higashiiru, Shimogyo-ku, Kyoto, 600-8009, Japan) DUO track. Scanning Electron Micrographs were obtained with an AMAT (Applied Materials, Inc. 3050 Bowers Avenue, P.O. Box 58039 Santa Clara, Calif. 95054-3299 U.S.A.) SEM. A Hitachi (Hitachi High Technologies America Inc. 10 North Martingale Road, Suite 500 Schaumburg, Ill. 60173-2295) S-5500 was used to examine cross sections SEM of Via Arrays produced. Contact angles were measured using a Kyowa (Kyowa Interface Science Co., Ltd. 5-4-41 Nobitome, Niiza-City, Saitama 352-0011, Japan) Interface Science Drop Master DY-700.

### Synthesis Example 1

### Synthesis of Azo Initiator with Phosphonate Pendant Groups

(1) 4,4′-Azobis(4-cyanopentanoyl chloride) as an isomer mixture: All procedures were conducted under nitrogen atmosphere. A suspension of 70 g of PCl₅ in about 240 ml of dichloromethane was prepared in a round bottom flask with a mechanical stirrer. To this suspension, 9.1 g of 4,4′-azobis(4-cyanovaleric acid) were added by portions within 25 minutes. The mixture was stirred for 2 hours at 0-2° C., then 40 hours while it warmed up to 16° C. The excess solid of phosphorus pentachioride was filtered off, washed with CH₂Cl₂ (2×10 ml). The resultant solution was concentrated using rotary evaporator at room temperature to give 115 g of colorless liquid. The material was then placed in a freezer at −20° C. for 4 hours. The cold solution was decanted into 200 ml of hexane with good stirring and a colorless solid was filtered and well washed with hexane. Yield: 7.3 g (70.8%); m.p. 75-77′C; ¹H NMR (CDCl₃, δ ppm) 1.68 (s) and 1.74 (s) (6H, 2×CH₃, 1:1.21 ratio), 2.4-2.65 (m) and 2.9-3.23 (m) (8H, 2×CH₂—CH₂, 1:1.14 ratio); ¹³C NMR (CDCl₃, δ ppm) 23.57 and 23.72 (CH₃), 32.87 (C_{q}—CH₂), 41.67 and 41.77 (CH₂—C(O)Cl), 71.26 and 71.4 (C_{q}), 116.77 and 116.87 (CN), 172.11 and 172.19 (C(O)Cl).

(2) N,N-bis(diethoxy-phosphorylethyl)amine: A solution was prepared by mixing 5.93 g of diethyl vinylphosphonate with log of concentrated ammonia in a round bottom flask and stirred for 45 h at room temperature. To the mixture, 40 ml of DI water was added. The product was extracted with dichloromethane (6×7 ml) and the organic phase was dried over Na₂SO₄. Stripping off the solvent from the solution afforded 4.1 g (66% yield) of N,N-bis(diethoxyphosphorylethyl)amine as a colorless liquid. ¹³C NMR (CDCl₃, δ ppm): 16.2 (d, J=6.08 Hz, CH₃), 26.3 (d, J=139.32 Hz, CH₂—P), 42.8 (d, J=2.76 Hz, CH₂—N), 61.4 (d, J=6.08 Hz, CH₂—O).

(3) 4,4′-Azobis[4-cyano-N,N-bis(diethoxyphosphorylethyl)pentanoyl amide] as an isomer mixture: A solution was prepared by dissolving 3.68 g of N,N-bis(diethoxy-phosphorylethyl)amine from above (2) and 0.7 g of triethylamine in 23 ml of anhydrous CHCl₃ in a round bottom flask. To the solution, 1.69 g of 4,4′-Azobis(4-cyanovaleric acid chloride) from above (1) were added by portions within 15 minutes with stirring for 1 hour at 0-3° C., and then 3 hours while it warmed up to ambient temperature. The reaction mixture was washed with water (5×5 ml) and dried over Na₂SO₄. Solvent stripping from the solution in vacuo at room temperature yielded 4.92 g (98%) of yellow-greenish viscous liquid. ¹H NMR (CDCl₃, δ ppm): 1.34 (t, 24H, 8×O—CH₂—CH₃, J=7.04 Hz), 1.65 (s) and 1.74 (s) (6H, 2×CH₃, 1:1.2 ratio), 2.02 (m, 8H, 4×CH₂—P), 2.63-2.34 (m, 8H 2×CH₂—CH₂—O(O)), 3.54 (m, 8H, 4×CH₂—N), 4.08 (m, 16H, 8×O—CH₂—CH₃);

### Synthesis Example 2

### Synthesis of Polystyrene Brush Precursor with Phosphonate End Group

In a 250 nil flask equipped with a magnetic stirrer, water condenser and gas bubbler a solution was made consisting of 1.7234 g (1.84 mmol) of the azo initiator prepared in above example 1 (3), 44.779 g (0.43 mol) of styrene dissolved in 60 ml of 2-butanone. Nitrogen gas was bubbled through the solution for 45 minutes, and while stirring the mixture was heated to 80° C. for 15.5 hours. The reaction mixture was cooled to room temperature and the solution was poured slowly into 1.8 L of MeOH under stirring. The polymer was isolated by filtration, dried (60° C.) and purified through reprecipitation from 95 ml of THF solution into 1.3 L of methanol, washed with methanol and dried at 60° C. in a vacuum oven until constant weight of 20.4 g, yield: 43.9%. Mn 23086 g/mol; Mw 40616 g/mol; PD 1.76. ¹H NMR (CDCl₃, δ ppm): 3.58-3.4 (m, —CH₂—N), 4.18-3.98 (m, CH₃—CH₂—O—P);

### Synthesis Example 3

### Synthesis of Azo Initiator with Hydroxy Pendant Groups

(1) A solution of tetramethylammonium pentahydrate was prepared by dissolving 63 g of this material in (0.348 mole) 100 g of methanol. This solution was slowly added to a solution of 48.72 g (0.174 moles) of 4,4′-azobis(4-cyanovaleric acid) suspended in 100 g of methanol with stirring at a rate of addition such that the temperature of the reaction did not rise above 40° C. After the addition was complete the reaction mixture was stirred for an additional hour. After this time the reaction mixture was mostly stripped of methanol under with a rotary evaporator at room temperature. This concentrated reaction mixture was then poured into a flask containing diethyl ether thereby precipitating an oily layer at the bottom of the flask. The supernatant ether was then poured off and the oily residue retained. Into the flask containing the oily residue more diethyl ether was added with stirring to wash the residue. This was repeated once more. Acetone was then poured into the washed oily residue, precipitating a white solid which was filtered and allowed to dry in a flow of nitrogen. 70 g (95% yield) of product was obtained. ¹H NMR (CDCl₃, δ ppm) 1.5 (s) (6H, 2×CH₃), 2.05-2.56 (m) (8H, 2×CH₂—CH₂); 3.77 (s) (24H, 2×4×CH₃)

(2) A solution was prepared by dissolving 41.3 g of NaI in 150 g of acetone. To this solution was added a solution prepared by dissolving 31.9 g of 4-(chloromethyl)benzyl alcohol in 110 g of acetone. The reaction mixture was stirred for two days. After this time the mixture was filtered and the filtrate slowly poured into DI water precipitating a white solid which was filtered and washed with water. The filtered solid was dried under vacuum at 50° C. 35 g (75% yield) of product was obtained. 1H NMR (CDCl₃, δ ppm) 4.43 (s) (2H, CH₂OH), 4.47 (s) (2H, CH₂I), 6.86-7.23 (m) (4H, phenyl).

(3) 20 g of the azo ammonium salt from step (1) was dissolved in a minimum amount of methanol while stirring. To this solution was added 150 g of DMSO, followed by a solution consisting of 22.8 g of 4-iodomethylbenzyl alcohol from step (2) dissolved in about 50 g of DMSO. This mixture was stirred at room temperature for 1 day, filtered to remove precipitated tetramethylammonium iodide and the filtrate precipitated into DI water. This precipitated was dissolved in acetone, filtered and the filtrate precipitated again in DI water. The precipitate was washed with DI water and dried under a flow of nitrogen giving 17 g (70% yield) of product. ¹H NMR (CDCl₃, δ ppm) 1.28 (s) (6H, 2×CH₃), 1.57-2.27 (m) (8H, 2×CH₂CH₂), 4.34 (s) (4H, 2×CH₂OH), 4.94 (s) (4H, 2×CH₂—O—), 6.8-6.9 (m) (8H, phenyl).

### Synthesis Example 4

### Synthesis of poly(styrene-r-methyl methacrylate) brush precursor with hydroxyl end group

To a 2-L flask equipped with a condenser, temperature controller, heating mantle and mechanical stirrer, was added under nitrogen 500 grams (4.80 moles) of styrene, 160 g (1.60 moles) of methyl methacrylate, 530 g of Methyl Ethyl Ketone (MEK) and 40 g (0.077 moles) of the Azo initiator made in Synthesis Example 3.

This reaction mixture was degassed by bubbling nitrogen through the solution while stirring. After degassing, the stirred solution was heated to 80° C. and reacted at this temperature for 20 hours. After this time, the cooled reaction mixture was poured into 15 L of methanol while stirring the methanol and the polymer precipitated. The precipitated polymer was filtered, dried under vacuum at 40° C. and dissolved in 1500 g of tetrahydrofuran (THF) a mechanical stirring, and the solution filtered. The filtered solution was precipitated into methanol. The dissolution into THE, filtering of the resultant solution, precipitation into methanol and filtering of the polymer was repeated once more and the final precipitated polymer dried under vacuum at 40° C. In this manner 460 g (70% yield) of polymer was obtained with Mw 18,000, PD 1.7; 70.0 mole % styrene repeat unit and 30 mole % methyl methacrylate repeat unit.

### Example 1

### Block Copolymer Formulation 1

The block copolymer from Polymer Source Inc. (124 Avro Street, Dorval (Montreal), Quebec, Canada) (P8205-SMMA) 68 k-b-33.5 k MMA-Styrene (Mw of 101.5 k Polydispersity (PD) 1.08) was dissolved in PGMEA to form a 1.2 weight solution and filtered through a 0.2 micron PTFE filter.

### Example 2

### Block Copolymer Formulation 2

The block copolymer from Polymer Source Inc. (P2400-SMMA) 46 k-b-21 k MMA-Styrene (Mw of 67 k Polydispersity 1.09) was dissolved in PGMEA to form a 1.2 weight % solution and filtered through a 0.2 micron PTFE filter.

### Example 3

### Block Copolymer/Brush Precursor Polymer Formulation 1

The block copolymer from Polymer Source Inc. (124 Avro Street, Dorval (Montreal), Quebec, Canada) (P2400-SMMA) 46 k-b-21 k MMA-Styrene (Mw of 67 k Polydispersity 1.09) (1.02 g) and the brush polymers from Polymer Source Inc. (124 Avro Street, Dorval (Montreal), Quebec, Canada) (P8758-SOH) hydroxyl terminated polystyrene (Mw of 19 k Polydispersity (PD) 1.15) (0.18 g) were dissolved in PGMEA to form a 1.2 weight % solution and filtered through a 0.2 micron PTFE filter.

### Example 4

### Block Copolymer/Brush Precursor Polymer/Thermal Acid Generator Formulation 1

The block copolymer from Polymer Source Inc. (124 Avro Street, Dorval (Montreal), Quebec, Canada) (P8966-SMMA P2400-SMMA) 18K-b-18K 46 k-b-21 k MMA-Styrene (Mw of 36K 67 k Polydispersity 1.09) (1.02 g) and the brush polymers from Polymer Source Inc. (124 Avro Street, Dorval (Montreal), Quebec, Canada) (P8758-SOH) hydroxyl terminated polystyrene (Mw of 19 k Polydispersity (PD) 1.15) (0.18 g) and thermal acid generator from Angene Chemical (4/F Silvercord Center Tower 1, 30 Canton Rd, KL, Hong Kong) (AG-F-56228) p-nitrobenzyl tosylate (0.018 g) were dissolved in PGMEA to form a 1.218 weight % solution which was filtered through a 0.2 micron PTFE filter.

### Example 5

### Block Copolymer/Brush Precursor Polymer Formulation 1

The block copolymer from Polymer Source Inc. (124 Avro Street, Dorval (Montreal), Quebec, Canada) (P2400-SMMA) 46 k-b-21 k MMA-Styrene (Mw of 67 k Polydispersity (PD) 1.09) (1.02 g) and the brush polymers from Polymer Source Inc. (124 Avro Street, Dorval (Montreal), Quebec, Canada) (P9678-SOH) hydroxyl terminated polystyrene (Mw of 12 k Polydispersity (PD) 1.04) (0.18 g) were dissolved in PGMEA to form a 1.2 weight % solution and filtered through a 0.2 micron PTFE filter.

### Example 6a

### Polystyrene Polymer Brush Precursor with Hydroxy End Group Solution

The polystyrene brush precursor with a hydroxyl end group from Polymer Source Inc. (124 Avro Street, Dorval (Montreal), Quebec, Canada) (P8758-SOH) hydroxyl terminated polystyrene (Mw of 19 k Polydispersity (PD) 1.15) was dissolved in PGMEA to form a 2.0 weight % solution and filtered through a 0.2 micron PTFE filter.

### Example 6b

### Polystyrene Polymer Brush Precursor with Phosphonate End Group

The Phosphonate brush precursor of Synthetic Example 3(3) was dissolved in PGMEA to form a 2.0 weight % solution and filtered through a 0.2 micron PTFE filter.

### Comparative Example 1

### Polystyrene Solution Comparative Formulation 1

Polystyrene from Polymer Source Inc. (124 Avro Street, Dorval (Montreal), Quebec, Canada) (P8605-S) (Mw of 21 k Polydispersity (PD) 1.04) was dissolved in PGMEA to form a 2.0 weight % solution and filtered through a 0.2 micron PTFE filter.

### Comparative Example 2

### Poly(Styrene-r-PMMA) Solution Comparative Formulation 2

Poly(styrene-r-methyl methacrylate) from Polymer Source Inc. (124 Avro Street, Dorval (Montreal), Quebec, Canada) (P9130 D-SMMAran) Polystyrene-MMA random copolymer (Mw of 23 k Polydispersity (PD) 1.3) was dissolved in PGMEA to form a 2.0 weight % solution and filtered through a 0.2 micron PTFE filter.

### Comparative Example 3

### Poly(Styrene-r-PMMA) Hydroxyl Terminated Solution Comparative Formulation 3

The poly(styrene-r-methyl methacrylate) brush precursor with hydroxyl end group of Synthesis Example 4 was dissolved in PGMEA to form a 2.0 weight % solution and filtered through a 0.2 micron PTFE filter.

### Example 7A

### Procedure for Formation of Post Guide Array (I) Using Post Type Photoresist Pattern by 193 nm Imaging Process

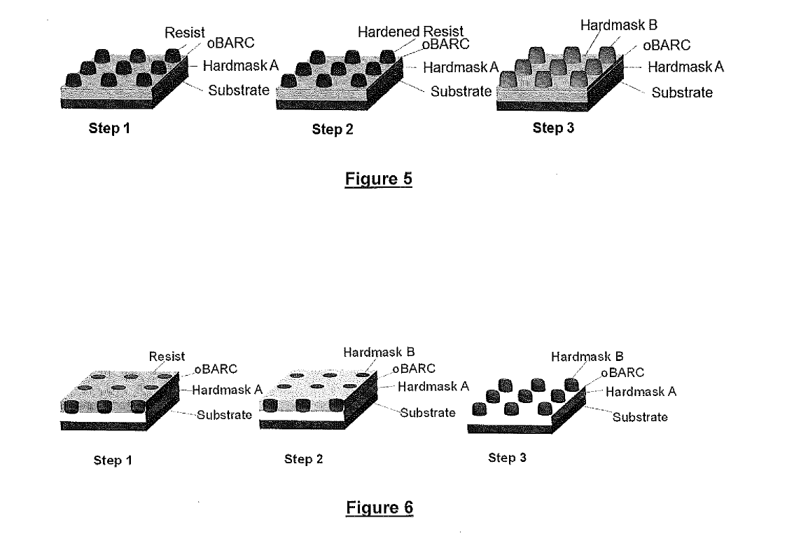

This post guide array (Pillar size: 40˜100 nm and Pitch size: 80˜200 nm: Pillar height: 50˜200 nm) was prepared using photoresist posts as follows and as illustrated in FIG. 5:

In a first step a substrate was coated by deposition with a Hardmask A which was comprised of a layer of SiO₂ formed by PECVD (Plasma Enhanced Chemical Vapor Deposition). Using a SOKUDO DUO track the hardmask A was coated with a Nissan ARC29 bottom antireflective (35 nm) and baked at 205° C. for 1 minute coating. A photoresist JSR AIM-5484 was coated (105 nm) (available from JSR Micro Inc. 1280 N Mathilda Ave, Sunnyvale, Calif. 94089) and post applied baked (120° C. 11 min) on the antireflective coating. Imaging was done with an X-grid double patterning by ASML NXT-1950 (1.35 NA, 0.82/0.62 dipole-x) post exposure baked at 110° C. for 60 s and developed with a 0.26 N TMAH developer (AZ 300 MIF) for 45 s to form the photoresist pillar array pattern. In a second step the photoresist pillars were hardened using an HBr plasma treatment by a LAM Versys etcher with a plasma processing chamber pressure of approximately 5 mT, a power of 1200 W, substantially 0 bias voltage applied to a chuck electrode, a HBr gas flow rate of 100 sccm (standard cubic centimeters per minute) and a cure time of approximately 60 seconds. In a third step, once the photoresist was hardened, a 10 nm Silicon oxide was deposited by atomic layer deposition (ALD). ALD was performed from 125-300° C. in a viscous-flow ALD reactor using TPS (tris(tert-pentoxy)silanol) and TMA (trimethyl aluminum). Nitrogen was used as a carrier gas on the H₂O and TMA lines. The total N₂ flow rate was 150 sccm, and this flow rate produced a pressure of 0.5 Torr in the reactor. The reactants were TMA (Street, 98%), H₂O (Fischer Scientific, Optima purity), and TPS (SAFC Hitech, 99.99%). The TPS was held in a stainless steel bubbler and maintained between 75-150° C. to obtain a range of vapor pressures. The TMA was contained in a gas cylinder and was maintained at room temperature. The H₂O was held in a glass cold finger and also maintained at room temperature. Alternatively, the hardening of the photoresist pillars was also done by plasma enhanced chemical vapor deposition with a capacitive parallel plate plasma discharge with a deposition temperature of 180° C.

### Example 7B

### Procedure for Formation of Post Guide Array (2) Using C/H Type Photoresist Pattern by 193 nm Imaging Process

A Post Guide Array (2) (Pillar size: 40˜100 nm and Pitch size: 80˜200 nm: Pillar height: 50˜200 nm) was prepared as follows and as illustrated in FIG. 6.

In a first step a substrate was coated with a Hardmask A which is comprised of a layer of SiO₂ formed by PECVD (Plasma Enhanced Chemical Vapor Deposition) using a SOKUDO DUO track. The hardmask A was coated with a Nissan ARC29 bottom antireflective coating solution (35 nm) (available from Nissan Chemical America Corporation Nissan Chemicals Nissan Chemical America Corporation 10375 Richmond Avenue Suite 1000 Houston, Tex. 77042) and baked at 205° C. for 1 minute. A photoresist, JSR AIM-5484 (available from JSR Micro Inc. 1280 N Mathilda Ave, Sunnyvale, Calif. 94089) was coated on the antireflective coating (105 nm) and post applied baked (120° C./1 min). Imaging of the photoresist was done at 193 nm using X-grid double patterning with an ASML NXT-1950 (1.35 NA, 0.82/0.62 dipole-x) followed by a post exposure bake at 100° C. and NTD (Negative Tone Development) with n-butyl acetate (nBA) for 30 seconds to form the contact hole (C/H) array. In a second step the photoresist contact hole array was hardened using an HBr plasma treatment using a LAM Versys etcher with a plasma processing chamber pressure of approximately 5 mT, a power of 1200 W, substantially 0 bias voltage applied to a chuck electrode, a HBr gas flow rate of 100 sccm (standard cubic centimeters per minute) and a cure time of approximately 60 seconds. Next, once the photoresist was hardened, a 10 nm silicon oxide was deposited by atomic layer deposition (ALD). ALD was performed from 125-300° C. in a viscous-flow ALD reactor using TPS (tris(tert-pentoxy)silanol) and TMA (trimethyl aluminum). Nitrogen was used as a carrier gas on the H₂O and TMA lines. The total N₂ flow rate was 150 sccm, and this flow rate produced a pressure of 0.5 Torr in the reactor. The reactants were TMA (Strem, 98%), H₂O (Fischer Scientific, Optima purity), and TPS (SAFC Hitech, 99.99%). The TPS was held in a stainless steel bubbler and maintained between 75-150° C. to obtain a range of vapor pressures. The TMA was contained in a gas cylinder and was maintained at room temperature. The H₂O was held in a glass coldfinger and also maintained at room temperature. Alternatively, the hardening was also done by plasma enchanced chemical vapor deposition with a capacitive parallel plate plasma discharge with a deposition temperature of 180° C.

In a third step the photoresist was stripped to form the pillar array by O₂ plasma ashing with LAM Versys etcher under a chamber pressure of 10 mTorr and 1000 watt using 200 sccm 02 for 45 seconds.

### Comparative Example 3

### Formation of Via Array Using No Pretreatment of Pillars Comparative Process 1

The solution of Block Copolymer Formulation 1 with the adjusted solid content targeting a final film thickness of 80 nm was spin-coated at a spin speed of 1500 rpm on a patterned wafer which had silicon dioxide pillars with a diameter of 80 nm in a 500 by 500 triangular array having a spacing of 60 nm which were made by the procedure of Example 7A using an SiO₂ thickness of 100 nm. The coated wafer was subsequently baked using a flow/grafting bake of 160° C./60 s. Subsequent to this flow bake the film was subjected to an annealing bake of 250° C./300 s. After the annealing bake the self-assembled polymer structure was subjected to a wet etching. The wet etching was done by blanket exposing the self-assembled polymer film with 200 mJ/cm² of 172 nm radiation and developing with a solution of isopropyl alcohol (IPA) for 120 sec. The Cross-section scanning electron microscope (XSEM) data CDSEM showed that via formation was poor because many ring defects occurred near the surface of the pillars, where highly etchable methyl methacrylate repeat units domains had self-assembled due to the hydrophilic nature of the pillars.

### Comparative Example 4

### Formation of Via Array Using Pretreatment of Pillars with Polystyrene Solution Comparative Formulation 1

The Polystyrene solution Comparative Formulation 1 with the adjusted solid content targeting final film thickness of 150 nm was spin-coated at a spin speed of 1500 rpm on a patterned wafer which had pillar of silicon dioxide with a diameter of 80 nm in a 500 by 500 triangular array having a spacing made by the procedure of Example 7A using an SiO₂ thickness of 100 nm. The coated wafer was subsequently baked using a bake of 240° C./300 s. After the bake the wafer was washed with PGMEA solvent for 120 second to remove any ungrafted polymer. After drying it, the block copolymer solution of Example 1 with an adjusted solid content targeting final film thickness of 80 nm was spin-coated on the treated pillar wafer. Subsequent to this a flow bake the 160° C./60 sec was applied to the coated wafer and subjected to an annealing bake of 250° C./300 s. After the annealing bake the self-assembled polymer structure was subjected to wet etching. The wet etching was done by blanket exposing the self-assembled polymer film with 200 mJ/cm² of 172 nm radiation. The Cross-section scanning electron microscope (XSEM) examination showed that via formation still occurred with many defects without any improvement over comparative example 3 in which no pretreatment of the pillars was employed.

### Comparative Example 5

### Formation of Via Array Using Pretreatment of Pillars with Poly(Styrene-r-PMMA) Comparative Formulation 2

The Poly(styrene-r-PMMA)(solution Comparative Formulation 2 with the adjusted solid content targeting final film thickness of 150 nm was spin-coated at a spin speed of 1500 rpm on a patterned wafer which had pillars of silicon dioxide with a diameter of 80 nm in a 500 by 500 triangular array having a spacing of 60 nm made by the procedure of Example 7A using an 100 nm thickness of SiO₂. The coated wafer was subsequently baked at 240° C./300 s. After the bake the wafer was washed with PGMEA solvent for 120 second to remove any ungrafted polymer. After drying it, the block copolymer solution Example 1 with the adjusted solid content targeting a final film thickness of 80 nm was spin-coated on the treated pillar wafer. Subsequent to this a flow bake of 160° C./60 sec was applied to the coated wafer and subjected to an annealing bake of 250° C./300 s. After the annealing bake the self-assembled polymer structure was subjected to wet etching. The wet etching was done by blanket exposing the self-assembled polymer film with 200 mJ/cm² of 172 nm radiation. The Cross-section scanning electron microscope (XSEM) examination showed that via formation still occurred with many defects without any improvement over comparative example 3 in which no pretreatment of the pillars was employed.

### Comparative Example 6

### Formation of Via Array Using Pretreatment of Pillars with Hydroxyl Terminated Poly(Styrene-r-PMMA) Brush Precursor of Comparative Formulation 3

The hydroxyl terminated Poly(styrene-r-PMMA) brush precursor solution of Comparative Formulation 3 with the adjusted solid content targeting final film thickness of 150 nm was spin-coated at a spin speed of 1500 rpm on a patterned wafer which had pillars of silicon dioxide with a diameter of 80 nm in a 500 by 500 triangular array having a spacing of 60 nm made by the procedure of Example 7A using a thickness of_SiO₂ of 100 nm. The coated wafer was subsequently baked at 240° C./300 s. After the bake the wafer was washed with PGMEA solvent for 120 second to remove any ungrafted polymer. After drying it, the block copolymer solution of Example 1 with the adjusted solid content targeting a final film thickness of 80 nm was spin-coated on the treated pillar wafer. Subsequent to this, a flow bake of 160° C./60 sec was applied to the coated wafer and subjected to an annealing bake of 250° C./300 s. After the annealing bake the self-assembled polymer structure was subjected to wet etching. The wet etching was done by blanket exposing the self-assembled film with 200 mJ/cm² of 172 nm radiation. The Cross-section scanning electron microscope (XSEM) examination showed that via formation still occurred with many defects without any improvement over comparative example 3 in which no pretreatment of the pillars was employed.

### Example 8

### Coating of Hydroxyl Terminated Brush Polymeric Brush Precursor on SiO₂ Pillars

A silicon wafer with SiO₂ Pillars having a height of 100 nm, a 140 nm pitch, and a diameter of 80 nm made by the procedure of Example 7A using a thickness of SiO₂ of 100 nm with an initial water contact angle of 0 to 5° was coated at a spin speed of 1,500 rpm with the block precursor solution containing PS—OH polymer of Example 6a. The coated wafer was baked at 240° C. for 300 sec. After this bake, the ungrafted PS—OH material was removed by washing with PGMEA solvent for 120 seconds. A similar coating on an unpatterned SiO₂ substrate after drying of the film gave a contact angle for water of 80° as measured by Kyowa Interface Science DropMaster DY-700. This contact angle was determined by measuring the static contact angle with water drops that were about 1 μl in volume. The three measurement points used depended on the die shape. The drop contact angles were measured within 5 s by automatic analyzed protocol.

### Example 8a

### Coating of Phosphonate Terminated Polymer Brush Precursor on SiO₂ Pillars

A silicon wafer with a SiO₂ layer, with an initial water contact angle of 0 to 5° was coated at a spin speed of 1,500 rpm with the solution containing the Polystyrene Polymer Brush Precursor with Phosphonate End Group of Example 6b. The coated wafer was baked at 240° C. for 300 sec. The film gave a contact angle for water of 80° as measured by Kyowa Interface Science DropMaster DY-700. This contact angle was determined by measuring the static contact angle with water drops that were about 1 ul in volume. The three measurement points used depended on the die shape. The drop contact angles were measured within 5 s by automatic analyzed protocol.

### Example 9

### VIA Formation from Pillar Array Using “Dual Coat Process” Wet Etching

The solution of Brush Precursor Polymer Example 6a with the adjusted solid content targeting final film thickness of 150 nm was spin-coated at a spin speed of 1,500 rpm on a patterned wafer which had pillars of silicon dioxide with a diameter size of 80 nm arranged in a 500 by 500 triangular array having a spacing of 60 nm made by the procedure of Example 7A using a SiO₂ thickness of 100 nm. The coated wafer was subsequently baked using a grafting bake of 240° C./60 s. After the grafting bake the wafer was washed with PGMEA solvent for 120 second to remove any ungrafted polymer. After drying it, the block copolymer solution of Example 1 with the adjusted solid content targeting final film thickness of 80 nm was spin-coated on the treated pillar wafer. Subsequent to this, a flow bake of 160° C./60 sec was applied to the coated wafer and it was subjected to an annealing bake of 250° C./300 s. After the annealing bake the self-assembled polymer structure was subjected to a wet etching. The wet etching was done by blanket exposing the self-assembled film with 200 mJ/cm² of 172 nm radiation. The Cross-section scanning electron microscope (XSEM) data showed excellent film coating quality and good via formation with no defects.

### Example 10

### VIA Formation from Pillar Array Using “Dual Coat Process” Dry Etching

The solution of Brush Precursor Polymer Example 6a with the adjusted solid content targeting final film thickness of 150 nm was spin-coated at a spin speed of 1,500 rpm on a patterned wafer which had pillars of silicon dioxide with a diameter size of 80 nm in a 500 by 500 triangular array having a spacing of 60 nm made by the procedure of Example 7A using SiO₂ with a 100 nm thickness. The coated wafer was subsequently baked using a grafting bake of 240° C./300 s. After the grafting bake the wafer was washed with PGMEA solvent for 120 second to remove any ungrafted polymer. After drying it, the block copolymer solution Example 1 with an adjusted solid content targeting final film thickness of 80 nm was spin-coated on the treated pillar wafer. Subsequent to this, a flow bake of 160° C./60 sec was applied to the coated wafer and subjected to an annealing bake of 250° C./300 s. After the annealing bake the self-assembled polymer structure was subjected to dry plasma etching. The wet etching was done by using an oxygen plasma using a Nordson March RIE-1700, with a Chamber pressure of 0.26 Pa and 30 sccm oxygen under 50 W for 15 sec. The Cross-section scanning electron microscope (XSEM) data showed excellent film coating quality and good via formation with no ring defects.

### Example 11

### VIA Formation from Pillar Array Using “Single Coat Process” Wet Etching

The solution of Block Copolymer/Brush Precursor Polymer Example 3 with the adjusted solid content targeting final film thickness of 80 nm was spin-coated at a spin speed of 1,500 rpm on a patterned wafer which had pillars of Silicon dioxide with a diameter of 80 nm in a 500 by 500 triangular array having a spacing of 60 nm made by the procedure of Example 7A using an SiO₂ thickness of 100 nm. The coated wafer was subsequently baked using a flow/grafting bake of 160° C./120 s. Subsequent to this flow bake the film was subjected to an annealing bake of 250° C./300 s. After the annealing bake the self-assembled polymer film was subjected to wet etching. The wet etching was done by blanket exposing the self-assembled film with 200 mJ/cm² of 172 nm radiation. The Cross-section scanning electron microscope (XSEM) data showed excellent film coating quality and good via formation with no ring defects.

### Example 12

### VIA Formation from Pillar Array Using “Single Coat Process” Dry Etching

The solution of Block Copolymer/Brush Precursor Polymer Example 3 with the adjusted solid content targeting final film thickness of 80 nm was spin-coated at a spin speed of 1,500 rpm on a patterned wafer which had pillars of Silicon dioxide with a diameter of 80 nm in a 500 by 500 triangular array having a spacing of 60 nm made by the procedure of Example 7A using an SiO₂ thickness of 100 nm. The coated wafer was subsequently baked using a flow/grafting bake of 160° C./120 s. Subsequent to this flow bake the film was subjected to an annealing bake of 250° C./300 s. After the annealing bake the self-assembled polymer film was subjected to a dry plasma etching. The wet etching was done by using an oxygen plasma employing a Nordson March RIE-1700 with a Chamber pressure was 0.26 Pa and 30 sccm oxygen under 50 W for 15 sec. The Cross-section scanning electron microscope (XSEM) data showed excellent film coating quality and good via formation with no defects.

### Example 13

### VIA Formation from Pillar Array Using “Single Coat Process” with Added Thermal Acid Generator and Wet Etching

The solution of Block Copolymer/Brush Precursor Polymer Example 4 containing the thermal acid generator p-nitrobenzyl tosylate with the adjusted solid content targeting final film thickness of 80 nm was spin-coated at a spin speed of 1,500 rpm on a patterned wafer which had pillars of silicon dioxide with a diameter of 80 nm arranged in a 500 by 500 triangular array having a spacing of 60 nm made by the procedure of Example 7X using an SiO₂ thickness of 100 nm thickness. The coated wafer was subsequently baked using a flow/grafting bake of 160° C./60 s. Subsequent to this flow bake the film was subjected to an annealing bake of 250° C./300 s. After the annealing bake the self-assembled polymer film was subjected to wet etching. The wet etching was done by blanket exposing the self-assembled film with 200 mJ/cm² of 172 nm radiation. The Cross-section scanning electron microscope (XSEM) data showed excellent film coating quality and good via formation with no ring defects.

### Example 14

### VIA Formation from Pillar Array Using “Single Coat Process” with Added Thermal Acid Generator and Dry Etching

The solution of Block Copolymer/Brush Precursor Polymer Example 4 containing the thermal acid generator p-nitrobenzyl tosylate with the adjusted solid content targeting final film thickness of 80 nm was spin-coated at as spin speed of 1,500 rpm on a patterned wafer which had pillars of silicon dioxide, 80 nm in diameter in a 500 by 500 triangular array having a spacing of 60 nm made by the procedure of Example 7A using an SiO₂ thickness of 100 nm. The coated wafer was subsequently baked using a flow/grafting bake of 160° C./60 s. Subsequent to this flow bake the film was subjected to an annealing bake of 250° C./300 s. After the annealing bake the self-assembled polymer was subjected to a dry plasma etching. The wet etching was done by using an oxygen plasma using a Nordson March RIE-1700 with a Chamber pressure of 0.26 Pa and 30 sccm oxygen under 50 W for 15 sec. The Cross-section scanning electron microscope (XSEM) data showed excellent film coating quality and good via formation with no ring defects.

### Summary of Unexpected Results Solving the New Problem of Ring Defects

The use of lithographic guiding pillars pattern to form an array of via's which are unfunctionalized in a direct assembly process with a styrene methythacrylate block copolymer resulted in the formation of ring defects during pattern transfer because of the assembly of the highly etchable MMA domains at the interphase interface of the directing pillars (comparative Example 3). Treatment of the pillars with a solution of polymers without reactive hydroxyl end groups such as solution of polystyrene (Comparative Example 4) or poly(styrene-r-methyl methacrylate) (Comparative Example 5) still resulted in the formation of ring defects during pattern transfer. Similarly, it was also found that the use of solution of poly(styrene-r-methyl methacrylate) with a reactive hydroxyl end group to treat the guiding pillars (Comparative Example 6) still resulted in many ring defects during pattern transfer. Unexpectedly, only the use of treating solutions containing a polystyrene (i.e. example of poly(vinyl aryl)) with a reactive end group such as hydroxyl gave no ring defects during pattern transfer, thus solving the problem caused by formation of these defects. Treating with solutions of the reactively terminated poly(vinyl aryl) by itself (Examples 9, 10) in a dual coat process or alternatively a solution containing both hydroxyl terminated polystyrene, the random copolymer (Example 11 and 12) and optionally also a thermal acid generator (Examples 13 and 14) could all be employed to dramatically reduce defect formation. When using a single coat process it was found that the use of a thermal acid generator in the solution containing both the polystyrene with hydroxyl end group and the poly(styrene-b-methyl methacrylate) resulted in better grafting of the hydroxyl terminated polyhydroxystyrene and gave the most reduction in defect formation during pattern transfer (Examples 13 and 14).

1) A process for making multiple via's from an original regular array of hydrophilic pillars comprising the steps of;
i) coating a planar thin film over a substrate comprising an original regular array of hydrophilic pillars from a first coating solution comprising a hydrophobic polymer brush precursor, where the hydrophobic polymer brush precursor is comprises vinyl aryl repeat units and where the polymer is terminated at one chain end by a reactive functional group chosen from the group consisting of hydroxyl (—OH), amino (—NH₂), phosphonic acid (—P═O(OH)₂) and phosphonic acid alkyl ester —P═O(OR)₂, where R is a C₁-C₄ alkyl group, and further where the thin film has a contact angle with water of about 75° to about 90° and a solvent;
ii) baking the thin film, thus grafting the reactive functional group terminated chain end of the hydrophobic polymer brush precursor to the hydrophilic surface on the coated pillars and thereby forming a hydrophobic coating on the pillars;
iii) removing the non-grafted hydrophobic polymer brush precursor with a solvent;
iv) coating the hydrophobic coated pillars with a second coating solution of a block copolymer to cover the pillars, wherein the block copolymer is comprises a hydrophobic etch resistant block and a hydrophilic highly etchable block;
v) applying a flow bake to the block copolymer film so as to conformably fill the pillar array;
vi) applying an annealing bake to affect self-assembly wherein the hydrophophic blocks of the block copolymer attach to the hydrophobic coated pillars; and,
vii) developing the self-assembled structure to form a final via array.

2) The process of claim 1 where the hydrophophic polymer terminated at one end by a reactive functional group in step i) is a poly(vinyl aryl) homopolymer.

3) The process of claim 2 wherein poly(vinyl aryl) homopolymer has structure (1) 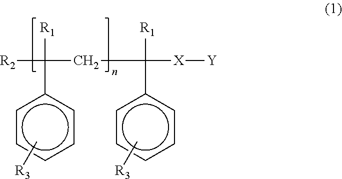
wherein R₁ is independently hydrogen, a C₁-C₄ alkyl, or a C₁-C₄ fluorinated alkyl, R₂ is hydrogen, a C₁-C₄ alkyl, a C₃-C₈ branched, an alkyl nitroxide group having structure (2), or a azo end group having structure (3) where R₄, R₅ and R₆ are independently C₁-C₈ alkyl or C₃-C₈ branched alkyl and further where R₄ and R₅ may be joined by a convalent bond forming a ring, R₃ is hydrogen, a C₁-C₈ alkyl, a C₁-C₈ alkyloxy, a C₁-C₈ fluorinated alkyl, a C₃-C₈ branched alkyl, a C₃-C₈ branched fluoroalkyl, a C₃-C₈ cycloalkyl, a C₃-C₈ cyclofluoroalkyl, or a halide; and further where is a X is a C₁-C₁₂ alkylene spacer moiety or a cyano substituted alkylene spacer moiety where X=—C(R₇)(CN)-(A₁)-A₂-(A₃)- and where R₇ is C₁-C₈ alkyl group, and A₁ and A₃ are C₁-C₆ alkylene moieties, and A₂ is direct bond or a heteroatom containing spacer moiety chosen from amide (—NH—C═O—) or (—C═O—NH—), ester (—O—C═O—) or (—C═O—O—), or ether (—O—); and further where Y is a functional group chosen from the group consisting of hydroxyl (—OH), amino (—NH₂), phosphonic acid (—P═O(OH)₂) and phosphonic acid alkyl ester —P═O(OR)₂, where R is a C₁-C₄ alkyl group and n represents the number of repeat units in the polymer

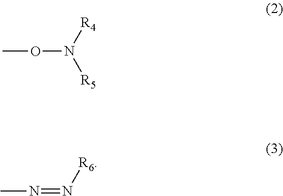

4) The process of claim 3 where R₁ is hydrogen, R₂ is a nitroxide group having structure (2), R₃ is hydrogen, X is —CH₂— and Y is hydroxyl.

5) The process of claim 3 where R₁ is hydrogen, R₂ is hydrogen, R₃ is hydrogen, and X is C(R₇)(CN)-(A₁)-A₂-(A₃) and where R₇ is C₁-C₈ alkyl group, A₁ and A₃ are C₁-C₆ alkylene moieties, and A₂ is direct bond or a heteroatom containing spacer moiety chosen from amide (—NH—C═O—) or (—C═O—NH—), ester (—O—O═O—) or (—O═O—O—), or ether (—O—); and further where Y is a functional group chosen from the group consisting of hydroxyl (—OH), amino (—NH₂), phosphonic acid (—P═O(OH)₂) and phosphonic acid alkyl ester —P═O(OR)₂, where R is a C₁-C₄ alkyl group.

6) The process of claim 1 where the block copolymer is poly(alkyl methacrylate-block-vinyl aryl compound) block copolymer, a poly(alkyl acrylate-block-vinyl aryl compound) block copolymer, a poly(alkyl methacrylate-block-vinyl nitrogen heterocylic aryl compound) block copolymer, or a poly(alkyl acrylate-block-vinyl nitrogen heterocylic aryl compound) block copolymer.

7) The process of claim 1 where the block copolymer is a methyl methacrylate and styrene block copolymer.

8) The process of claim 1 where the block copolymer is a block copolymer of methyl methacrylate and 4-vinylpyridine.

9) The process of claim 1 where in step v) the annealing bake is between 180° C. and 250° C. and is done in air.

10) A process for making multiple via's from an original regular array of hydrophilic pillars comprising the steps of,
i) coating the hydrophilic pillars with a third coating solution wherein the coating solution comprises a mixture of a hydrophobic polymer brush precursor comprising vinyl aryl repeat units and where the polymer is terminated at one chain end by a reactive functional group chosen from the group consisting of hydroxyl (—OH), amino (—NH₂), phosphonic acid (—P═O(OH)₂) and phosphonic acid alkyl ester —P═O(OR)₂, where R is a C₁-C₄ alkyl group, where the hydrophobic polymer brush precursor, if coated in a thin film, has a contact angle with water of 75° to 90°; a block copolymer and a solvent and further wherein the block copolymer comprises a hydrophobic etch resistant block and a hydrophilic highly etchable block; and
ii) applying a flow and grafting bake to the coating film so as to fill the pillar array and to graft the hydrophobic polymer brush precursor;
iii) applying an annealing bake to affect self-assembly, where the hydrophophic blocks of the block copolymer attach to the pillars; and,
iv) developing the self-assembled structure to form a final via array.

11) The process of claim 10 where the hydrophophic polymer terminated at one end by a reactive functional group in step i) is a poly(vinyl aryl) homopolymer.

12) The process of claim 11 where in step i) the polymer is terminated at one chain end by reactive functional group has structure (1) 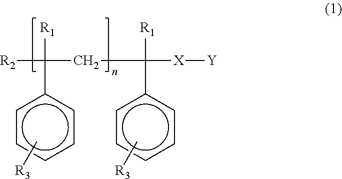
wherein R₁ is independently hydrogen, a C₁-C₄ alkyl, or a C₁-C₄ fluorinated alkyl, R₂ is hydrogen, a C₁-C₄ alkyl, a C₃-C₈ branched, an alkyl nitroxide group having structure (2), or a azo end group having structure (3) where R₄, R₅ and R₆ are independently C₁-C₈ alkyl or C₃-C₈ branched alkyl and further where R₄ and R₅ may be joined by a convalent bond forming a ring, R₃ is hydrogen, a C₁-C₈ alkyl, a C₁-C₈ alkyloxy, a C₁-C₈ fluorinated alkyl, a C₃-C₈ branched alkyl, a C₃-C₈ branched fluoroalkyl, a C₃-C₈ cycloalkyl, a C₃-C₈ cyclofluoroalkyl, or a halide, and further where X is a C₁-C₁₂ alkylene spacer moiety or a cyano substituted alkylene spacer moiety where X=—C(R₇)(CN)-(A₁)-A₂-(A₃)- and where R₇ is C1-C8 alkyl group, A₁ and A₃ are C₁-C₆ alkylene moities, and A₂ is direct bond or a heteroatom containing spacer moiety chosen from amide (—NH—C═O—) or (—C═O—NH—), ester (—O—C═O—) or (—C═O—O—), or ether (—O—); and further where Y is a functional group chosen from the group consisting of hydroxyl (—OH), amino (—NH₂), phosphonic acid (—P═O(OH)₂) and phosphonic acid alkyl ester —P═O(OR)₂, where R is a C₁-C₄ alkyl group and n represents the number of repeat units in the polymer

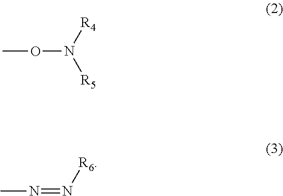

13) The process of claim 10 where the block copolymer is a poly(alkyl methacrylate-block-vinyl aryl compound) block polymer, a poly(alkyl acrylate-block vinyl aryl compound) block copolymer, a poly(alkyl methacrylate-block-vinyl nitrogen heterocyclic aryl compound) block copolymer or a poly(alkyl acrylate-block-vinyl nitrogen heterocyclic aryl compound) block copolymer.

14) The process of claim 10 where the block copolymer is a methyl methacrylate styrene block copolymer.

15) The process of claim 10 where the block copolymer is a block copolymer of methyl methacrylate and 4-vinylpyridine.

16) The process of claim 10 wherein in step iii) the annealing bake is between 180° C. and 250° C. and is done in air.

17) The process of claim 10 where the in step i) the solution further comprises at least one thermal acid generator.

18) A composition for making multiple via's from an original regular array of hydrophilic pillars comprising;
i) a hydrophobic polymer brush precursor comprising vinyl aryl repeat units where the polymer is terminated at one chain end by a functional group chosen from the group consisting of hydroxyl (—OH), amino (—NH₂), phosphonic acid (—P═O(OH)₂) and phosphonic acid alkyl ester —P═O(OR)₂, where R is a C₁-C₄ alkyl group, and further where the hydrophobic polymer brush precursor, when coated in a film, has a contact angle with water of 75° to 90°;
ii) a block copolymer where the block copolymer comprises a hydrophobic etch resistant block and a hydrophilic highly etchable block;
iii) a thermal acid generator; and,
iv) and solvent.

19) The composition of claim 18 where the hydrophobic the polymer terminated at one chain end by a functional group has structure (1) 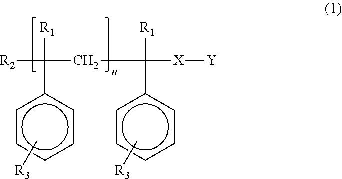
wherein R₁ is independently hydrogen, a C₁-C₄ alkyl, or a C₁-C₄ fluorinated alkyl, R₂ is hydrogen, a C₁-C₄ alkyl, a C₃-C₈ branched, an alkyl nitroxide group having structure (2), or a azo end group having structure (3) where R₄, R₅ and R₆ are independently C₁-C₈ alkyl or C₃-C₈ branched alkyl and further where R₄ and R₅ may be joined by a convalent bond forming a ring, R₃ is hydrogen, a C₁-C₈ alkyl, a C₁-C₈ alkyloxy, a C₁-C₈ fluorinated alkyl, a C₃-C₈ branched alkyl, a C₃-C₈ branched fluoroalkyl, a C₃-C₈ cycloalkyl, a C₃-C₈ cyclofluoroalkyl, or a halide, and further where X is a C₁-C₁₂ alkylene spacer moiety or a cyano substituted alkylene spacer moiety where X=—C(R₇)(CN)-(A₁)-A₂-(A₃)- and where R₇ is C₁-C₈ alkyl group, A₁ and A₃ are C₁-C₆ alkylene moities, and A₂ is direct bond or a heteroatom containing spacer moiety chosen from amide (—NH—C═O—) or (—C═O—NH—), ester (—O—C═O—) or (—C═O—O—), or ether (—O—); and further where Y is a functional group chosen from the group consisting of hydroxyl (—OH), amino (—NH₂), phosphonic acid (—P═O(OH)₂) and phosphonic acid alkyl ester —P═O(OR)₂, where R is a C₁-C₄ alkyl group and n represents the number of repeat units in the polymer.

20) The composition of claim 18 where the thermal acid generator is chosen from o-nitrobenzyl esters of sulfonic acid, p-nitrobenzyl esters of sulfonic acids, 5-norbornene-2,3-dicarboximidyl-N-esters of sulfonic acid, dicarboximidyl esters of sulfonic acid, oxime sulfonates, ammonium salts of primary amines and a sulfonic acid, ammonium salts of secondary amines and a sulfonic acid, ammonium salts of a tertiary amine and a sulfonic acid or mixtures of these
